(19) United States
(12) Patent Application Publication
(10) Pub. No.: US 2025/0208183 A1
(43) Pub. Date: Jun. 26, 2025

(54) PUSHER FOR USE IN AN AUTOMATED TEST EQUIPMENT, A TEST ARRANGEMENT COMPRISING THE PUSHER AND A METHOD FOR MECHANICALLY PUSHING THE DEVICE UNDER TEST WITH A SINGLE-LINEARLY POLARIZED ANTENNA INTO A DEVICE UNDER TEST SOCKET

(71) Applicant: Advantest Corporation, Tokyo (JP)

(72) Inventors: Jan HESSELBARTH, Stuttgart (DE); José MOREIRA, Stuttgart (DE)

(21) Appl. No.: 19/078,433

(22) Filed: Mar. 13, 2025

Related U.S. Application Data
(63) Continuation of application No. PCT/EP2022/075585, filed on Sep. 14, 2022.

(51) Int. Cl. G01R 29/08

(52) U.S. Cl. CPC G01R 29/0871; G01R 29/0892

(57) ABSTRACT

An embodiment according to the invention has a pusher for use in an automated test equipment (ATE) to mechanically push a device under test having an antenna or an antenna array into a DUT socket. The pusher has a structure, in which there are alternating parallel layers of relatively higher dielectric permittivity and relatively lower dielectric permittivity. The layers of higher dielectric permittivity and lower dielectric permittivity extend in a first direction, which is within ±45° of a pushing direction.

### CROSS-REFERENCE TO RELATED APPLICATION

This application is a continuation of copending International Application No. PCT/EP2022/075585, filed Sep. 14, 2022, which is incorporated herein by reference in its entirety.

### TECHNICAL FIELD

Embodiments according to the present invention relate to a pusher configured to push a device under test (DUT) into a device under test socket. Embodiments according to the present invention relate to a pusher configured to push a device under test with single-linearly polarized antenna(s) into a device under test socket. Further embodiments relate to a test arrangement comprising a device under test to be pushed into a device under test socket (DUT-socket) by a pusher. Further embodiments according to the invention relate to a concept and/or design of a high-transparency pusher for planar antenna modules. Embodiments according to the present invention relate to a high-transparency pusher for over-the-air test-sockets.

### BACKGROUND OF THE INVENTION

Millimeter-wave transceiver modules often comprise electronics and planar antennas in a device of or with a small form factor. The size of the module is often determined by the antenna aperture area or by the antenna array aperture area. Such a module is usually preferred (sometimes required) to be over-the-air (OTA) tested in an automated test equipment (ATE) at or in production environment. Handling and/or testing the modules may require pushing the module mechanically into a DUT-socket by a pushing means or pusher on or onto the side of the antenna or antenna array aperture.

The DUT antenna or antenna array is designed to have air and/or a (very) thin dielectric material layer on top of it so it does not disturb the DUT antenna or antenna array. For testing the DUT in an ATE or for ATE testing these conditions are mimicked or simulated partially by the pusher. The pusher, which can be part of an OTA socket and/or of a handler arm of an ATE or of an ATE test cell might be a critical part in an OTA testing, because it touches the antenna or antenna array in or of the DUT while pushing it down into a DUT-socket.

The problem of or with designing a pusher for an OTA test-socket is the material of the pusher. The material of the pusher is preferred to have a (very) low dielectric constant, which is close to the dielectric constant of air, or more broadly, the electric properties of the pusher-material is preferred to be close to the electric properties of air. Also, the pusher-material is preferred to be mechanically strong to support the mechanical stress of multiple cycles of pushing the DUT into the DUT-socket. In other words, the pusher is preferred to be electromagnetically transparent, or nearly transparent, so as to avoid disturbing the single-linearly polarized antenna(s) of the DUT, while being mechanically solid and stiff. Unfortunately, due to physical reasons, there is no material available that has both of these properties.

Dielectric materials with (very) low relative permittivity are known to fulfil the need of electromagnetic transparency, but at the same, these materials are mechanically soft. On the contrary, a mechanically stiff pusher is made of a high permittivity material, which can cause a de-tuning of the antenna feed impedance and/or can change the antenna radiation pattern.

Thus, there is a need for a pusher, which has an optimum performance with respect to electromagnetic transparency as well as mechanical stiffness.

### SUMMARY OF THE INVENTION

An embodiment may have a pusher for use in an automated test equipment to mechanically push a device under test into a device under test socket, wherein the pusher has a structure in which there are alternating layers of higher dielectric permittivity and layers of lower dielectric permittivity, and wherein the layers extend in a first direction, which is within +/−45° of a pushing direction.

Another embodiment may have a test arrangement for testing a device under test, having a device under test with an antenna pushed into a device under test socket by a pusher according to the invention as mentioned above in order to test the device under test.

Another embodiment may have a method for mechanically pushing a device under test into a device under test socket of an automated test equipment, wherein the method has mechanically pushing the device under test into the device under test socket with a pusher, which has a structure, in which there are alternating layers of higher dielectric permittivity and layers of lower dielectric permittivity, and wherein the layers are extending in a first direction, which is within +/−45° of a pushing direction.

An embodiment according to the invention comprises a pusher for use in an automated test equipment (ATE) to mechanically push a device under test (DUT) comprising an antenna or an antenna array into a DUT socket. The pusher comprises a structure, in which there are alternating parallel layers of relatively higher dielectric permittivity and relatively lower dielectric permittivity. The layers of higher dielectric permittivity and lower dielectric permittivity extend in a first direction, which is within ±45° of a pushing direction.

To address the challenge of having a mechanically stiff but electromagnetically transparent or nearly transparent, pusher, the embodiment of the pusher or the structure of the pusher has a hybrid design in which mechanically soft materials with low dielectric constant and mechanically strong materials with high dielectric constant are comprised and/or mixed. A pusher with this hybrid design can be applied to push DUTs with single-polarized antennas.

In other words, the design of the pusher and dimensions of the high permittivity dielectric layers and/or of the low permittivity dielectric layers of the pusher might be important or critical for the pusher in order to avoid an impact (or an excessive impact) on the electromagnetic waves received or transmitted by the DUT antenna or DUT antenna array. The layers of high dielectric permittivity are improving the mechanical stiffness of the pusher, while the layers of low dielectric permittivity are improving the electromagnetic transparency of the pusher.

Also, the fact that the higher permittivity dielectric layers extend in a direction, which is within ±45° parallel to the pushing direction, or surfaces of parallel layers are within ±45° perpendicular to the pushing direction, also improves the stability, the durability and the mechanical stiffness of the pusher.

In an embodiment, a ratio between a thickness of the layers of the higher dielectric permittivity and a thickness of the layers of lower dielectric permittivity is between 1:10 and 2:1.

The main requirements against the pusher are a mechanical stiffness and an electromagnetic transparency. The thickness of layers of higher dielectric permittivity and of lower dielectric permittivity are chosen so that the pusher may remain transparent, or nearly transparent, for the electromagnetic waves transmitted or received by the antenna or the antenna array of the DUT while remaining mechanically stiff to be used to push a DUT into a DUT-socket. Based on previous conducted experiments, a ratio between 1:10 and 2:1 fulfills this requirement.

According to embodiments, the structure, with alternating layers of higher dielectric permittivity and of lower dielectric permittivity, comprises between 9 and 66.6 vol. % or between 20 and 60 vol. % relatively higher permittivity dielectric regions and between 91 and 33.3 vol. % or between 80 and 40 vol. % relatively lower permittivity dielectric regions. Advantageously, the structure comprises between 30 and 50 vol. % relatively higher permittivity dielectric regions and between 70 and 50 vol. % relatively permittivity dielectric regions.

A well-chosen ratio between the relatively higher permittivity dielectric regions or layers of higher dielectric permittivity and the relatively lower permittivity dielectric regions or layers of lower dielectric permittivity results in a pusher, which remains transparent, or nearly transparent, for the electromagnetic waves transmitted or received by the antenna or the antenna array of the DUT, while remaining mechanically stiff to be used to push a DUT into a DUT-socket.

In an embodiment, the surface of the pusher, which is configured to touch the device under test, is formed or configured or machined, so that the pusher avoids touching or approaching close-by, e.g. within a distance of 1/10 of a wavelength of an electromagnetic wave transmitted or received by an antenna of the DUT, a conductive edge of the antenna of the DUT. The conductive edge might be a metallic edge of the antenna structure, which contributes strongly to the radiation.

Touching or approaching close-by the DUT-antenna by the pusher affects negatively a performance of the antenna of the DUT. Dielectric loading of the radiating edges of DUT-antennas or their close proximity affect their resonance. Changing the resonance changes the feed impedance and the radiation behavior of the antenna. Moreover, if the pusher is large compared to the wavelength and has a not-small permittivity, it is of advantage to avoid arbitrary resonances within the pusher itself, which would lead to changes (sometimes disastrous changes) of radiation and feed characteristics.

In an embodiment, the pusher comprises a spacer configured to be in between the structure of alternating parallel layers and the DUT. The spacer is perpendicular, within a tolerance of +/−15° to the alternating parallel layers and/or the spacer is parallel, within a tolerance of +/−15°, to a surface of the DUT to be pushed by the pusher.

Benefits of the spacer is the exchangeability, so in any case, not the whole pusher has to be replaced, just the spacer. Also, if the pusher has to be adapted to a new DUT or in case of breakage, only the spacer is replaced, which saves costs and material.

In an embodiment, the spacer is a structured spacer, that is, it is further formed or configured or machined to touch the device under test, so that the spacer avoids touching or approaching close-by, e.g. within a distance of 1/10 of a wavelength of an electromagnetic wave transmitted or received by an antenna of the DUT, a conductive edge of the antenna of the DUT. The conductive edge might be a metallic edge of the antenna structure, which contributes strongly to the radiation.

As the spacer is exchangeable, each kind of antenna design could have a dedicated spacer, which avoids touching or approaching close-by the conductive edges of the antenna or antenna array of the DUT. That is, the same pusher could be applied with different spacers for different DUTs, making the pusher and thus the ATE more flexible.

In an embodiment, the spacer has a relative permittivity less than or equal to 1.5.

The spacer which is configured to be in closed contact with the DUT-antenna without touching or approaching close-by the conductive edges of the antenna is made of a low relative permittivity dielectric material in order to be transparent, or nearly transparent, for the electromagnetic waves received or transmitted by the antenna of the DUT.

In an embodiment, the spacer has a thickness of between 50 micrometers and 500 micrometers.

The spacer is configured to cover the whole surface area of the antenna of the DUT. The above mentioned thickness of between 50 and 500 micrometers helps to reach this even if the surface area of the antenna is uneven. Also, good mechanical stability can be achieved without excessively degrading antenna capabilities.

In an embodiment, the spacer has a thickness of between 100 micrometers and 200 micrometers.

If the antenna area of the DUT is slightly (or sufficiently) even, a thickness of between 100 micrometers and 200 micrometers might be also enough to cover the whole surface area of the antenna of the DUT.

In an embodiment, the pusher comprises a dielectric slab, e.g. a dielectric slab made of a mechanically stiff material with a relatively higher permittivity, which is transversal to or perpendicular, within a tolerance of +/−15°, to the pushing direction. The dielectric slab is configured to mechanically support and/or stabilize at least the layers of higher dielectric permittivity.

The mechanically stronger dielectric slab is transversal to the pushing direction and attached to the layers of higher dielectric permittivity. This makes the pusher more durable, stiffer and more stable, as for example, it prevents independent movements of single layers of higher dielectric permittivity of the pusher, if for example the surface of the DUT is uneven.

In an embodiment, the dielectric slab has a thickness, which equals, within a tolerance of 1/10 a wavelength of an electromagnetic wave transmitted or received by an antenna of the DUT, e.g., at a center frequency of an operation frequency band of the DUT, to an integer multiple of a half wavelength of an electromagnetic wave in the dielectric material of the dielectric slab, which calculates to the free space wavelength divided by the square-root of the relative permittivity of the dielectric, transmitted or received by the antenna of the DUT, e.g., at a center frequency of an operation frequency band of the DUT. The distance between the dielectric slab and the surface of the antenna of the device under test is at least one wavelength of the electromagnetic wave transmitted or received by the antenna of the DUT, e.g., at the center frequency band of an operation frequency band of the DUT.

The dielectric slab is made of a mechanically strong material, which has a relatively high permittivity. The dielectric slab advantageously is to be electromagnetically as transparent as possible. Thus, the thickness of the slab and/or the distance between the DUT-antenna and the slab is chosen in a way, that the negative effect of the slab on the electromagnetic waves transmitted or received by the antenna of the DUT is minimal, e.g. the loss of electromagnetic wave transmitted or received by the antenna of the DUT is minimal.

In an embodiment, a length of the alternating parallel layers in the pushing direction is between 0.5 and 2 times a free space wavelength of an electromagnetic wave transmitted or received by an antenna of the DUT, e.g., at the center frequency of an operation frequency band of the DUT.

The length of the alternating parallel layers, that is the length of the structure of the pusher, in the pushing direction, e.g. in the direction of the main lobe of the electromagnetic waves transmitted or received by the DUT-antenna, is defining for the amount of electromagnetic waves absorbed by the pusher. A pusher with limited length or the alternating parallel layers with limited length limits the amount of electromagnetic waves absorbed from the electromagnetic waves transmitted or received by the antenna of the DUT. Thus, with limited length of the alternating parallel layers, the pusher remains as transparent as possible to the electromagnetic wave received or transmitted by the antenna of the DUT, while remaining mechanically stiff.

In an embodiment, the relatively higher dielectric permittivity layers have a relative permittivity greater than 2 or advantageously between 2.5 and 4.

The relative permittivity of mechanically strong materials is high. Materials used for providing mechanical stability and strength to the pusher are found to have a relative permittivity of at least 2. A relative permittivity between 2.5 and 4 gives a good balance between mechanical strength and electromagnetic transparency.

In an embodiment the relatively higher dielectric permittivity layers are made of polymer or of polycarbonate or of quartz or of Teflon or of PEEK material.

In an embodiment, the relatively lower dielectric permittivity layers have a relative permittivity less than or equal to 1.5.

Relatively lower permittivity materials, with a permittivity of 1.5, are transparent or near to transparent to electromagnetic waves transmitted or received by the antenna of the DUT.

In an embodiment, the relative lower dielectric permittivity layers comprise air.

Air has a low relative permittivity. So in a simple pusher design only the relatively higher dielectric permittivity layers are built and the relatively lower dielectric permittivity layers are left void, e.g. are filled with air. In this case, the air around and/or between the relatively higher dielectric permittivity layers are part of the structure of the pusher.

In an embodiment, the pushing direction is parallel, with a tolerance of +/−15°, to a far-field direction of an electrical field in a main lobe of an antenna of the DUT. Alternatively, the pushing direction is perpendicular, within a tolerance of +/−15°, to the main surface of the DUT. A further option is that the pushing direction is perpendicular, within a tolerance of +/−15° to the main surface of the DUT socket.

In order to improve the transparency of the pusher to the electromagnetic waves transmitted or received by the DUT-antenna, the effective area of the structure of the pusher, in particular the effective area of the higher dielectric permittivity layers of the pusher, is minimized. The effective area of the structure is minimal, if the direction of the structure is, e.g. the extension of the layers are, parallel to the main lobe of the received or transmitted electromagnetic waves, which is in most cases also perpendicular, within a tolerance of +/−15°, to the main surface of the DUT or of the DUT-socket.

A further embodiment comprises a test arrangement for testing a device under test. The test arrangement comprises the device under test with an antenna or an antenna array, an above-discussed pusher and a device under test socket. The device under test with an antenna or an antenna array of the test arrangement is configured to be pushed into the device under test socket by the discussed pusher. The antenna of the DUT is a single-linearly polarized antenna.

Another embodiment according to the invention creates a method for mechanically pushing the device under test, comprising an antenna or an antenna array, into a device under test socket of an automated test equipment. The method comprising mechanically pushing the device under test into the device under test socket with an above-discussed pusher. The antenna of the DUT is a single-linearly polarized antenna.

It should be noted, that methods and corresponding apparatuses are based on the same considerations. Moreover, the methods may be supplemented by any of the features or functionalities and details which are described herein with respect to the apparatuses both individually and taken in combination.

### BRIEF DESCRIPTION OF THE FIGURES

Embodiments according to the present application will subsequently by described making reference to the enclosed figures, in which:

FIG. 1 shows a schematic representation of an embodiment of a test arrangement comprising a DUT socket, a DUT with antennas and an embodiment of a pusher;

FIG. 2 shows a schematic representation of an embodiment of a pusher configured to repeatedly push DUTs into a DUT-socket;

FIG. 3 shows a photo of an embodiment of a test arrangement without a DUT, comprising a pusher and a DUT socket with a test antenna;

FIG. 4 shows a Dielectric constant-Strength diagram, in which abscissa-values represent dielectric constant values, and ordinate-values represent flexural strength values;

FIG. 5a shows an initial DUT patch antenna without any pusher;

FIG. 5b shows a DUT patch antenna with a conventional pusher;

FIG. 5c shows a DUT patch antenna with a higher-permittivity dielectric slab;

FIG. 5d shows a DUT patch antenna with a pusher structure, comprising alternating parallel layers of relatively higher dielectric permittivity and of air or relatively lower dielectric permittivity;

FIG. 5e shows a DUT patch antenna with a lower-permittivity dielectric spacer;

FIG. 6a shows a 3D simulation of a DUT with a dual-polarized patch antenna;

FIG. 6b shows simulated input reflection coefficient measurement results on a diagram and on a Smith chart;

FIG. 7a shows a 3D simulation of an arrangement comprising a patch antenna and a conventional pusher;

FIG. 7b shows simulated input reflection coefficient measurement results on a diagram and on a Smith chart and radiation pattern in two exemplary, perpendicular cut-planes for one selected polarization of the dual-polarized antenna, when the relative permittivity of the pusher is 1.0;

FIG. 7c shows simulated input reflection coefficient measurement results on a diagram and on a Smith chart and radiation pattern in two exemplary, perpendicular cut-planes for one selected polarization of the dual-polarized antenna, when the relative permittivity of the pusher is 1.2;

FIG. 7d shows simulated input reflection coefficient measurement results on a diagram and on a Smith chart and radiation pattern in two exemplary, perpendicular cut-planes for one selected polarization of the dual-polarized antenna, when the relative permittivity of the pusher is 3.6;

FIG. 8a shows a 3D simulation of an arrangement comprising a patch antenna and a spacer layer;

FIG. 8b shows simulated input reflection coefficient measurement results on a diagram and on a Smith chart, when the relative permittivity of the spacer is 1.3;

FIG. 9a shows 3D simulations of three different test arrangements;

FIG. 9b shows the results of a simulated input reflection coefficient measurement conducted on the first 3D simulated test arrangement of FIG. 9a, in which no pusher is present;

FIG. 9c shows the results of a simulated input reflection coefficient measurement conducted on the second 3D simulated test arrangement of FIG. 9a, in which the pusher is a simplified brick and has a relative permittivity of 1.1;

FIG. 9d shows the results of a simulated input reflection coefficient measurement conducted on the second 3D simulated test arrangement of FIG. 9a, in which the pusher is a simplified brick and has a relative permittivity of 1.2;

FIG. 9e shows the results of a simulated input reflection coefficient measurement conducted on the second 3D simulated test arrangement of FIG. 9a, in which the pusher is a simplified brick and has a relative permittivity of 1.3;

FIG. 9f shows the results of a simulated input reflection coefficient measurement conducted on the third 3D simulated test arrangement of FIG. 9a, in which the pusher is a layered pusher of 39 slats having a relative permittivity of 1.3;

FIG. 9g shows the results of a simulated input reflection coefficient measurement conducted on the third 3D simulated test arrangement of FIG. 9a, in which the pusher is a layered pusher of 39 slats having a relative permittivity of 2.5;

FIG. 10a shows a 3D simulation of a test arrangement;

FIG. 10b shows the simulated test arrangement of FIG. 10a built up layer by layer over three images;

FIG. 10c shows results of a simulated input reflection coefficient measurement conducted on the test arrangement of FIG. 10a, comprising pusher with 39 slats and a structured spacer layer, with a relative permittivity of 2.5 and 1.3, respectively;

FIG. 10d shows results of a simulated input reflection coefficient measurement conducted on the test arrangement of FIG. 10a, comprising pusher with 39 slats and a structured spacer layer, with a relative permittivity of 3.1 and 1.3, respectively;

FIG. 10e shows results of a simulated input reflection coefficient measurement conducted on the test arrangement of FIG. 10a, comprising pusher with 39 slats and a structured spacer layer, with a relative permittivity of 3.6 and 1.3, respectively;

FIG. 11a shows two images of the same 3D simulated test arrangement comprising a pusher and a DUT with an antenna;

FIG. 11b shows results of a simulated input reflection coefficient measurement conducted on test arrangement of FIG. 11a, in which the pusher hasslats with a structured spacer layer, made of materials with a relative permittivity of 3.6 and 1.3 respectively;

FIG. 12a shows a simulated test arrangement, which is the simulated test arrangement FIG. 11a, with the pusher having an additional dielectric slab;

FIG. 12b shows results of a simulated input reflection coefficient measurements conducted on the test arrangement of FIG. 12a with a layered pusher of 15 slats and a structured spacer layer; and

FIG. 13 shows a comparison table with respect to the change of feed reflection coefficient.

### DETAILED DESCRIPTION OF THE INVENTION

In the following, different inventive embodiments and aspects will be described. Also, further embodiments will be defined by the enclosed claims. It should be noted that any embodiments as defined by the claims may optionally be supplemented by any of the details, features and functionalities described herein. Also, the embodiments described herein may be used individually, and may also optionally be supplemented by any of the details, features and functionalities included in the claims.

Also, it should be noted that individual aspects described herein may be used individually or in combination. Thus, details may be added to each of said individual aspects without adding details to another one of said aspects. It should also be noted that the present disclosure describes, explicitly or implicitly, features usable in an automatic test equipment, in a test arrangement or in a pusher. Thus, any of the features described herein may be used in the context of an automatic test equipment, in the context of a test arrangement or in the context of a pusher.

Moreover, features and functionalities disclosed herein, relating to a method, may also be used in an apparatus configured to perform such functionalities. Furthermore, any features and functionalities disclosed herein with respect to an apparatus may also be used in a corresponding method. In other words, the methods disclosed herein may be supplemented by any of the features and functionalities described with respect to the apparatuses.

The present invention will be understood more fully from the detailed description given below and from the accompanying drawings of embodiments of the present invention, which, however, should not be taken to limit the present invention to the specific embodiments described, but are for explanation and understanding only.

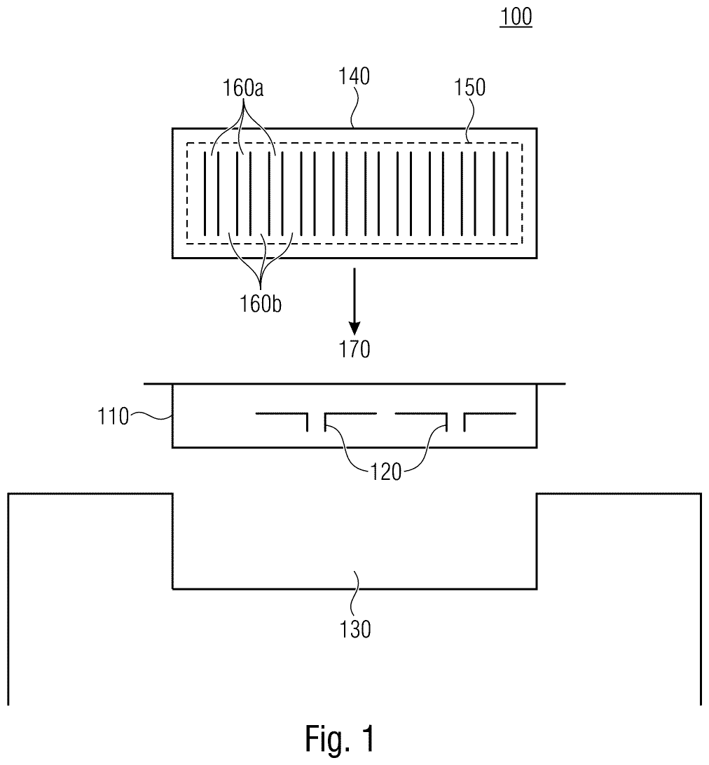

### Embodiment According to FIG. 1

FIG. 1 shows a schematic representation of an embodiment of a test arrangement 100 for testing a device under test (DUT) 110 comprising one or more antennas 120 and/or antenna arrays 120. The test arrangement 100 comprises a DUT socket 130, the DUT 110 with the antennas 120, and an embodiment of a pusher 140.

The test arrangement 100 is configured to test the DUT 110, in particularly the antennas 120 of the DUT 110. The DUT 110 is configured to be pushed in a pushing direction 170 into the device under test socket 130 by the pusher 140.

The pusher 140 is a schematic representation of an embodiment, which comprises a structure 150 comprising alternating parallel layers of relatively higher dielectric permittivity 160a and relatively lower dielectric permittivity 160b, in which the meaning of “relatively” is, that the permittivity of a given dielectric region is higher or lower relative to other dielectric regions of the pusher 140. The structure 150 and/or the alternating parallel layers of relatively higher dielectric permittivity 160a and relatively lower dielectric permittivity 160b extend in a direction within +/−45° of the pushing direction 170.

The pusher 140 is configured to mechanically push a device under test 110 comprising an antenna 120 or an antenna array 120 into a device under test socket 130 of an automated test equipment. The structure 150 of the pusher 140 with the alternating parallel layers of relatively higher dielectric permittivity 160a and relatively lower dielectric permittivity 160b improves significantly the transparency of the pusher 140 compared to conventional pushers for the electromagnetic waves transmitted or received by the antennas 120 of the DUT 110, while the pusher 140 remains mechanically stiff enough to repeatedly push DUTs 110 into a DUT socket 130 in a production environment.

The structure 150 comprises between 9 vol. % and 66.6 vol. % or between 20 and 60 vol. % higher permittivity dielectric regions 160a and between 91 vol. % and 33.3 vol. % or between 80 and 40 vol. % lower permittivity dielectric regions 160b. Advantageously, the structure comprises between 30 and 50 vol. % higher permittivity dielectric regions 160a and between 70 and 50% lower permittivity dielectric regions 160b.

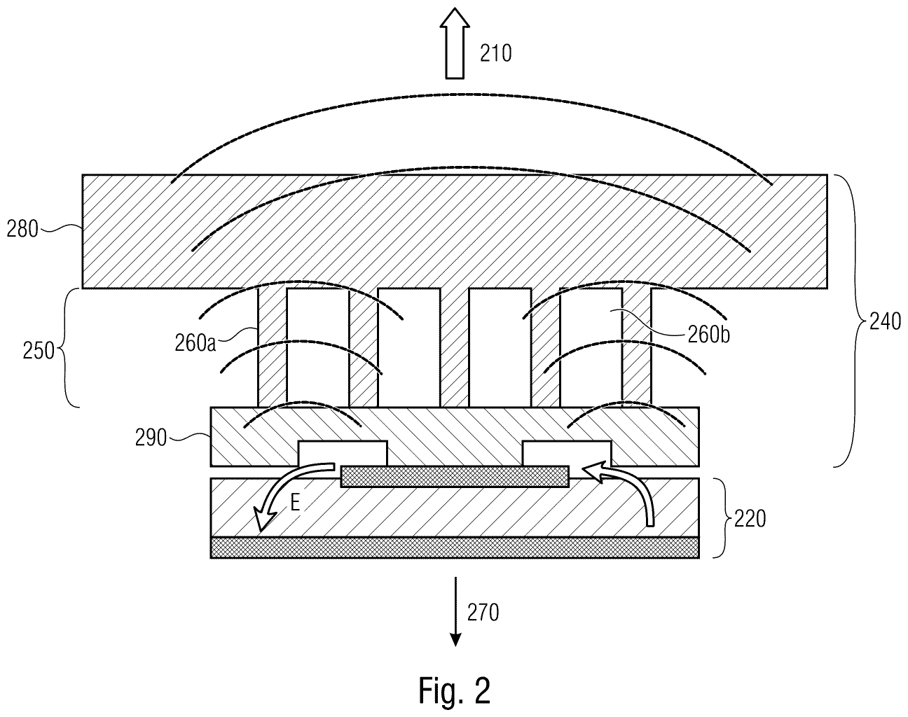

The layers of relatively higher dielectric permittivity 160a have for example, a relative permittivity greater than 2 or advantageously between 2.5 and 4, such as polymer or polycarbonate or quartz or Teflon or PEEK materials. The layers of relatively lower dielectric permittivity 160b have for example a relative permittivity less than or equal to 1.5. As shown in FIG. 2, the lower permittivity dielectric region may also comprise air.

### Embodiments According to FIG. 2

FIG. 2 shows a schematic representation of an embodiment of a pusher 240, similar to the pusher 140 of FIG. 1, with an antenna 220 of the DUT. The pusher comprises a spacer 290, a structure 250, in which there are alternating parallel layers of relatively higher dielectric permittivity 260a and of relatively lower dielectric permittivity 260b, and a dielectric slab 280.

The pusher 240 is configured to repeatedly push DUTs 220, similar to the DUT 110 of FIG. 1, into a DUT-socket. The DUTs comprise at least an antenna 220 or an antenna array transmitting or receiving electromagnetic waves 210. The antenna is a single-linearly polarized antenna.

The spacer 290 of the pusher is attached to the pusher structure 250 and configured to be in-between the structure 250 and the DUT or the antenna 220 of the DUT. The spacer is perpendicular within a tolerance of +/−15° to the surface of the alternating parallel layers 260a, 260b of the pusher 240. The spacer is made of a mechanically soft lower permittivity dielectric material, with a relative permittivity of less than 1.5. The spacer is configured or machined so that the spacer avoids touching or approaching close-by or within a distance of 1/10 of a wavelength of an electromagnetic wave transmitted or received by the antenna 220, a conductive edge of the antenna of the DUT. The conductive edge might be a metallic edge of the antenna structure, which contributes strongly to the radiation.

The dielectric slab 280 is attached to the higher permittivity dielectric columns 260a and is arranged transversal or perpendicular within a tolerance of +/−15° to the pushing direction 270.

The dielectric slab 280 of the pusher 240 is configured to mechanically support at least the layers of relatively higher dielectric permittivity 260a of the structure 250. In order to remain transparent or near to transparent for electromagnetic waves 210 transmitted or received by the antenna 220, the dielectric slab 280 has a thickness which equals an integer multiple of half a wavelength of the electromagnetic wave 210 in the dielectric material of the dielectric slab 280. This calculates to a free space wavelength divided by the square root of relative permittivity of the dielectric. The tolerance of the thickness is 1/10 of a wavelength of an electromagnetic wave transmitted or received by the antenna 220, e.g. at a center frequency of the operation frequency band of the DUT.

The structure 250 of the pusher is similar to the pusher structure 150 of FIG. 1, in which the length in the pushing direction of the alternating parallel layers 260a, 260b is between 0.5 and 2 times the free space wavelengths of an electromagnetic wave transmitted or received by the antenna 220 of the DUT.

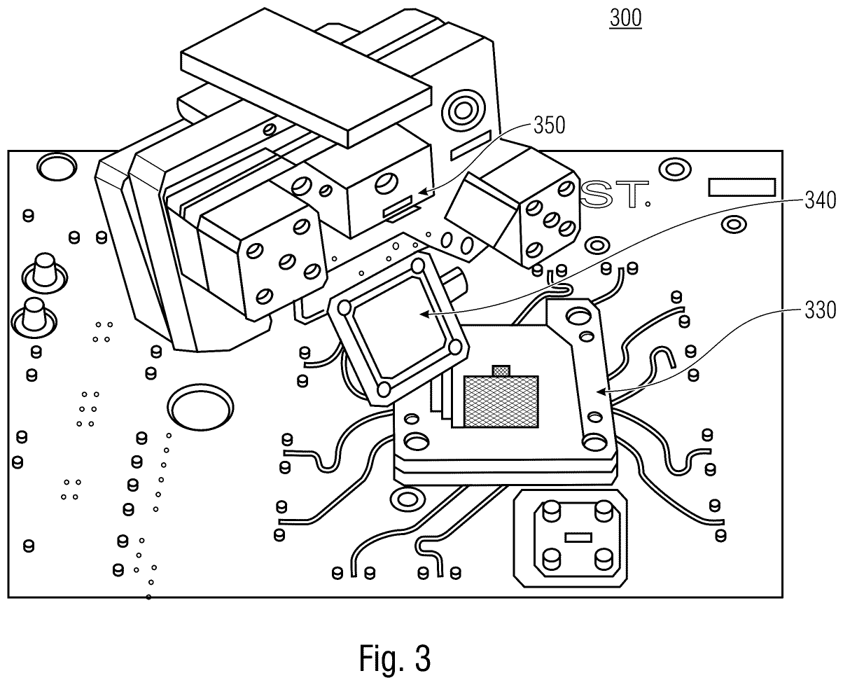

The pusher 240 can also be used in a test arrangement, similar to the test arrangement 100 of FIG. 1. A photo of the test arrangement with a pusher is to be found in FIG. 3.

### Embodiment According to FIG. 3

FIG. 3 shows a photo of an embodiment of a test arrangement 300, similar to the test arrangement 100 of FIG. 1. The test arrangement 300 comprises a pusher 340, similar to the pusher 140 of FIG. 1 or the pusher 240 of FIG. 2, and a DUT socket 330. The DUT of the test arrangement 300 is not shown, but FIG. 3 further shows a test antenna 350 of the automatic test equipment (ATE), which is configured to conduct over the air (OTA) tests or measurements on the DUT.

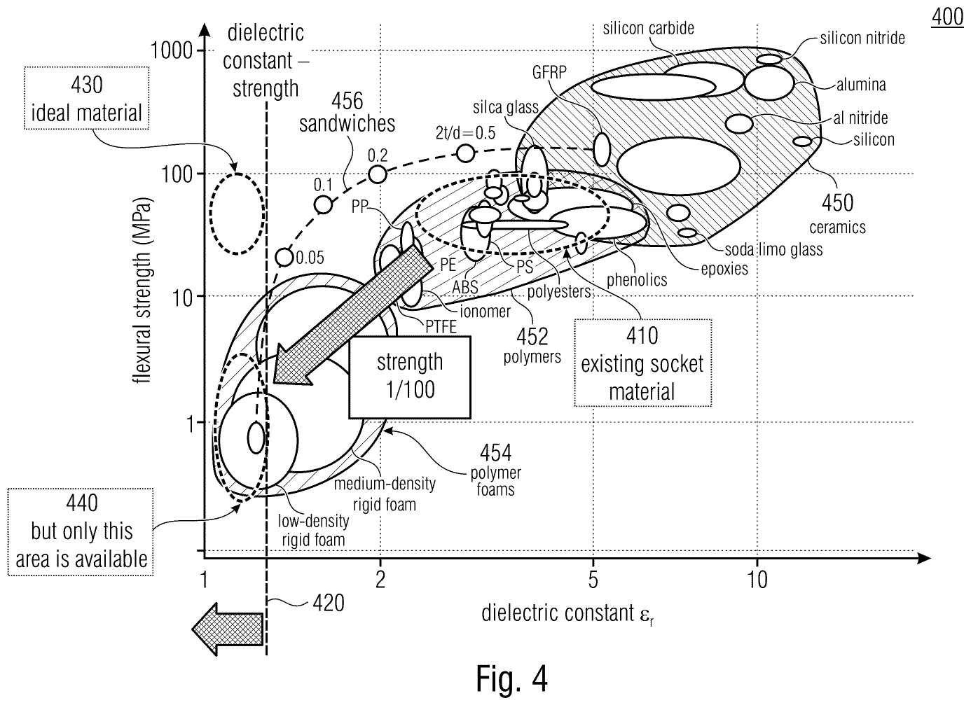

### Dielectric Constant-Strength Diagram According to FIG. 4

FIG. 4 shows a Dielectric constant-Strength diagram 400 in which abscissa-values represent dielectric constant values, and ordinate-values represent flexural strength values. Different materials are represented in this diagram, such as ceramics 450, polymers 452, polymer foams 454 and sandwiches 456. Existing pusher (or socket) materials 410, ideal pusher material 430 and available pusher materials 440 are also marked on this diagram.

It is shown that the existing pusher (or socket) materials 410 have a satisfactory flexural strength, but their dielectric constant is higher than ideal. A satisfactory dielectric constant would be on the left side of the line 420, or less than or equal to 1.5. The place of the ideal material 430 is illustrated in the diagram, but there are no known materials to match these requirements. Existing material with a dielectric constant of less than or equal to 1.5 is a type of polymer foam, with a flexural strength of 1/100^{th} of the existing or conventional pusher materials 410. The available materials 440 with a low dielectric constant, illustrated in the diagram, do not have the advantageous flexural strength.

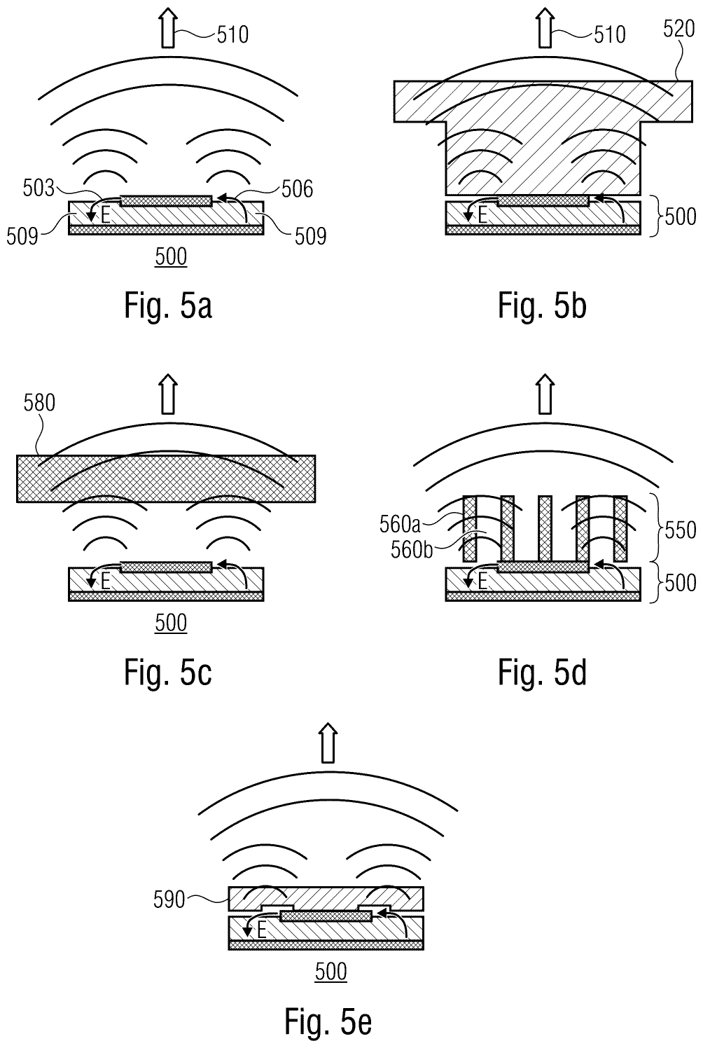

An ideal material, fulfilling the features of a low dielectric constant, e.g. lower than 1.5 and a higher flexural strength, higher than 30 MPa, is not known yet, and therefore an improved design concept is required. The design concepts applied in the pusher 240 of FIG. 2 is a combination of all the new ideas or design concepts of FIG. 5.

### Design Concept According to FIG. 5

FIG. 5a-e shows a schematic representation of existing and new pusher design concepts.

FIG. 5a shows the initial state, e.g. a patch antenna 500 without any pusher. The patch antenna 500 serves as a characteristic example of a planar antenna. It features two opposite radiating edges 503, 506 with an electric field 509 primarily perpendicular to these edges. Operating frequency and feed impedance are determined by the resonance of the electromagnetic field 509, which is enclosed between the ground and the patch and between the two radiating edges 503, 506.

That is, FIG. 5a shows an initial arrangement of a single patch antenna 500 without any pusher. The antenna radiates or transmits electromagnetic waves 510 which advantageously is not to be affected by a pusher in an ideal test arrangement.

FIG. 5b shows the patch antenna 500 of FIG. 5a with a conventional pusher 520, with a conventional design concept, having a whole or solid block of a pusher 520 configured to push the DUT-antenna 500 into the DUT socket. The conventional pusher 520 is made of a material, which is an existing pusher material 410 of FIG. 4. In this conventional design, the dielectric loading of the radiating edges, or their close proximity, affects the resonance of the DUT-antenna 500. The dielectric pusher 520 will change the resonance of the DUT-antenna 500, thereby changing the feed impedance and radiation behavior of the DUT-antenna 500. If the pusher is large, compared to wavelength, and having a not-small permittivity, it is of advantage to avoid arbitrary resonances within the pusher itself, which would eventually lead to significant or sometimes disastrous changes of the radiation and of the feed characteristics.

In order to have a pusher which avoids changing the resonance of the DUT-antenna 500 and thereby changing the feed impedance and radiation behavior, three dielectric structural features of a pusher with their particular electromagnetic features are introduced in the following three figures FIGS. 5c-e.

FIG. 5c shows a dielectric slab 580 of a solid, mechanically strong, higher-permittivity dielectric material, placed parallel to the antenna aperture plane of the DUT-antenna 500. The thickness of the slab 580 equals, within a tolerance of 1/10 a wavelength of an electromagnetic wave transmitted or received by the DUT-antenna 500, an integer multiple of a half wavelength of the electromagnetic wave in the dielectric material of the dielectric slab 580.

The distance between the DUT-antenna 500 and the dielectric slab 580 is at least one wavelength of the electromagnetic wave transmitted or received by the DUT-antenna 500. The solid, mechanically strong, higher-permittivity dielectric material, which is required for mechanical stability, is not intended to touch the radiating slots or the metallic or conductive edges of the antenna aperture plane, as this leads to detuning the feed impedance. The conductive edge might be a metallic edge of the antenna structure, which contributes strongly to the radiation.

FIG. 5d shows a patch antenna 500 with a pusher structure 550 of alternating parallel layers of relatively higher dielectric permittivity and of air or of relatively lower dielectric permittivity. The structure 550, e.g. a layered stack of thin sheets of higher-permittivity dielectric material separated by air or by low-permittivity spacer layers, offers a lower effective permittivity to an electric field perpendicular to the sheet plane, compared to a higher effective permittivity for an electric field parallel to the sheet plane.

Provided the direction of an electric field is known, then the appropriately oriented structure 550 or layered stack of thin sheets of higher-permittivity dielectric material 560a can have less influence on the DUT-antenna 500 performance.

FIG. 5e shows a DUT patch antenna 500 with a lower-permittivity dielectric spacer 590. A DUT with the patch antenna 500 is configured to be pushed by the spacer 590 or spacer layer 590 into a DUT socket.

The surface of planar antennas comprise, for example, dielectric surface areas, metal edges and metal surface areas. In terms of touching the surface with a dielectric pusher, the most sensitive areas are the metal edges and the dielectric areas close to them, as these may form radiating edges or slots, by the metal surfaces are rather non-critical.

Some structured dielectric spacer or spacer layer or sheet provides mechanical contacts between the planar antenna surface and the pusher only in the metal areas and in non-critical dielectric areas of the antenna surface. It is of advantage to leave the radiating edges or slots without direct contact, providing some small air spacer volume above these edges or slots.

The concept's ideas of FIGS. 5c and 5e are rather obvious and straightforwardly implemented, while the tradeoff between efforts and benefits is further quantified by the idea of FIG. 5d. The design concepts of FIG. 5a-e are simulated in the following figures.

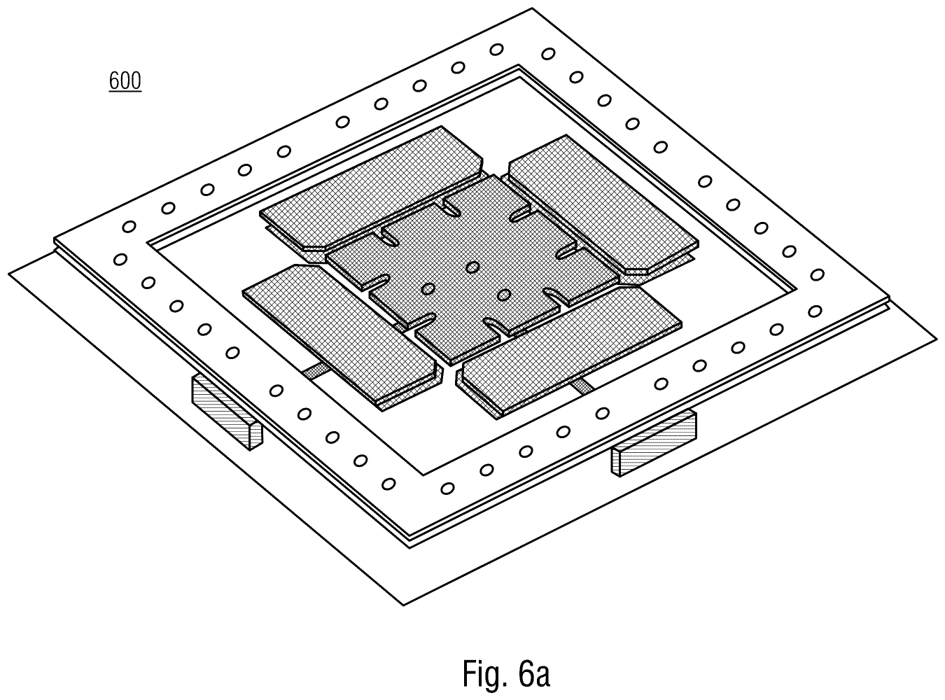

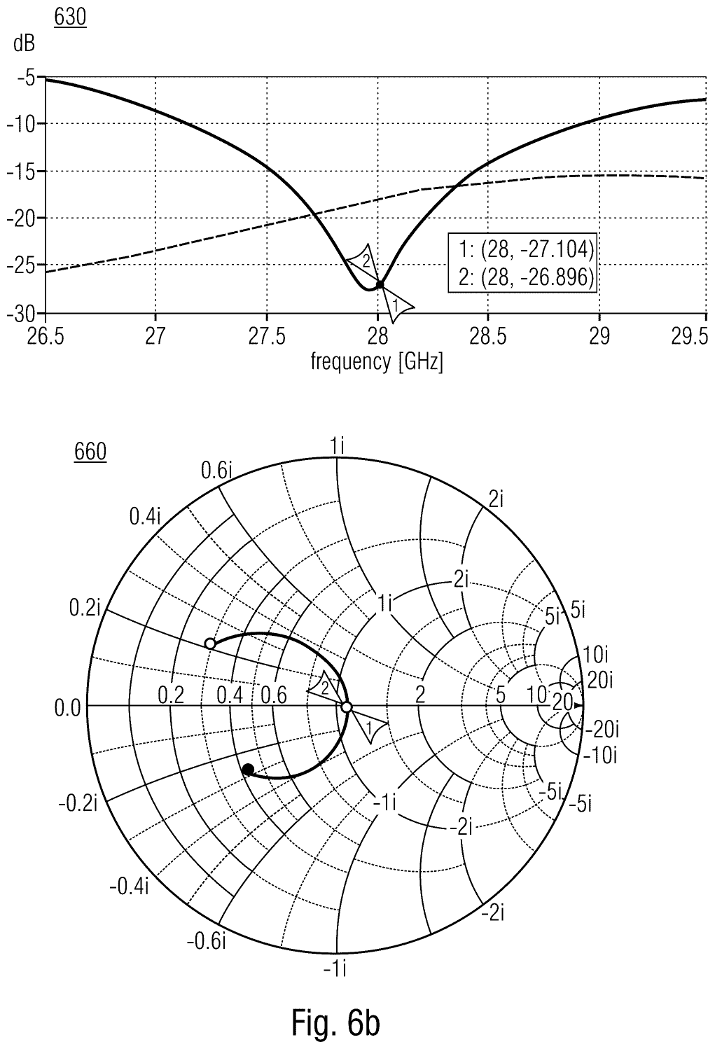

### Antenna Simulation According to FIG. 6

FIG. 6a shows a 3D simulation of a DUT with a dual-polarized patch antenna, which is a possible example of the patch antenna 500 of FIG. 5. The example antenna 600 used in FIG. 6 for quantifying performance in a simulation using electromagnetic field simulation software. The example antenna 600 is a dual-linearly polarized micro strip patch antenna. It is representative for the vast majority of planar antennas, as their operation and problems are common to all patch and slot antennas.

In the simulation a center frequency of operation of 28 GHz is used. The two feed lines are terminated in ports at a characteristic line impedance of about 35 Ohms.

FIG. 6b shows the simulated input reflection coefficient measurement results, in a frequency-reflection diagram 630 and on a Smith chart 660. The charts are showing the input reflection coefficients. Markers correspond to about (40.9+j1.0)Ω at 28 GHz.

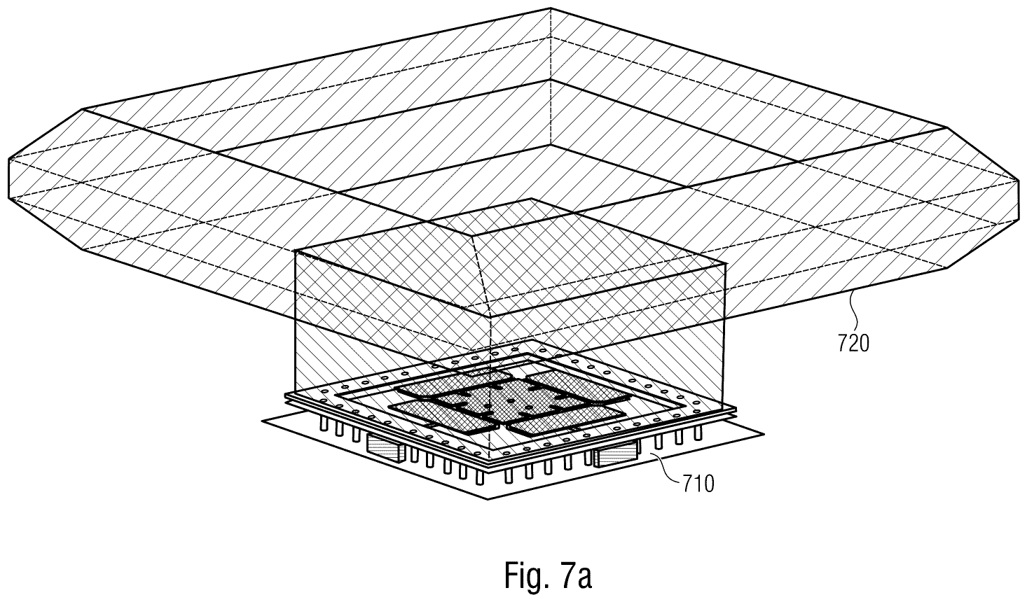

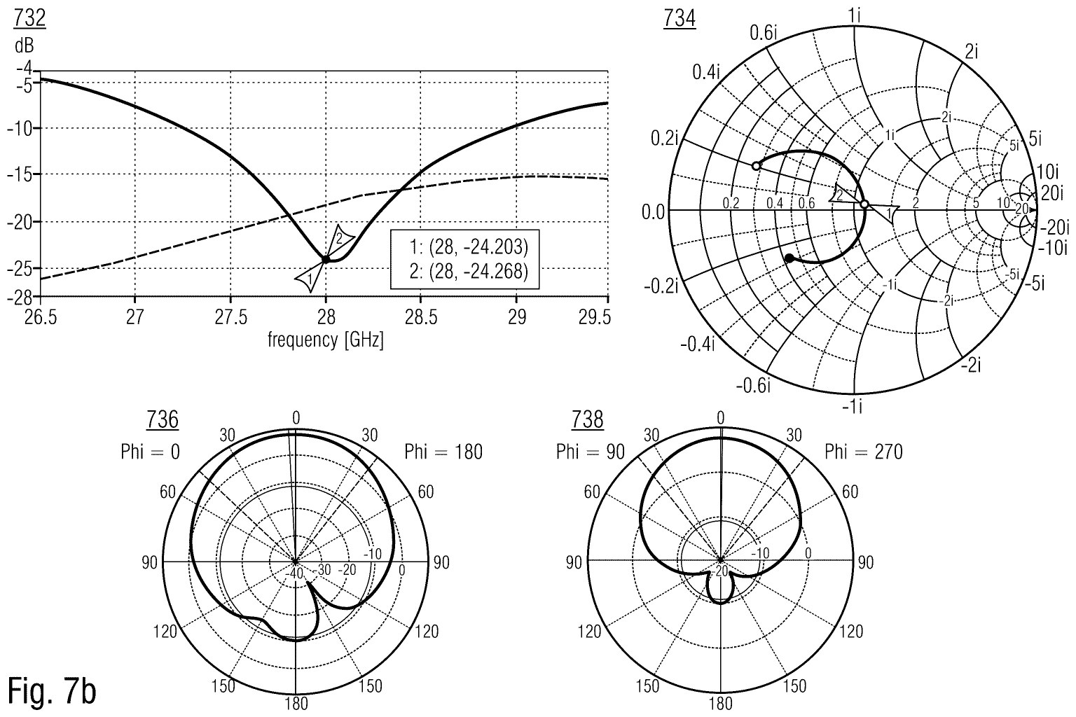

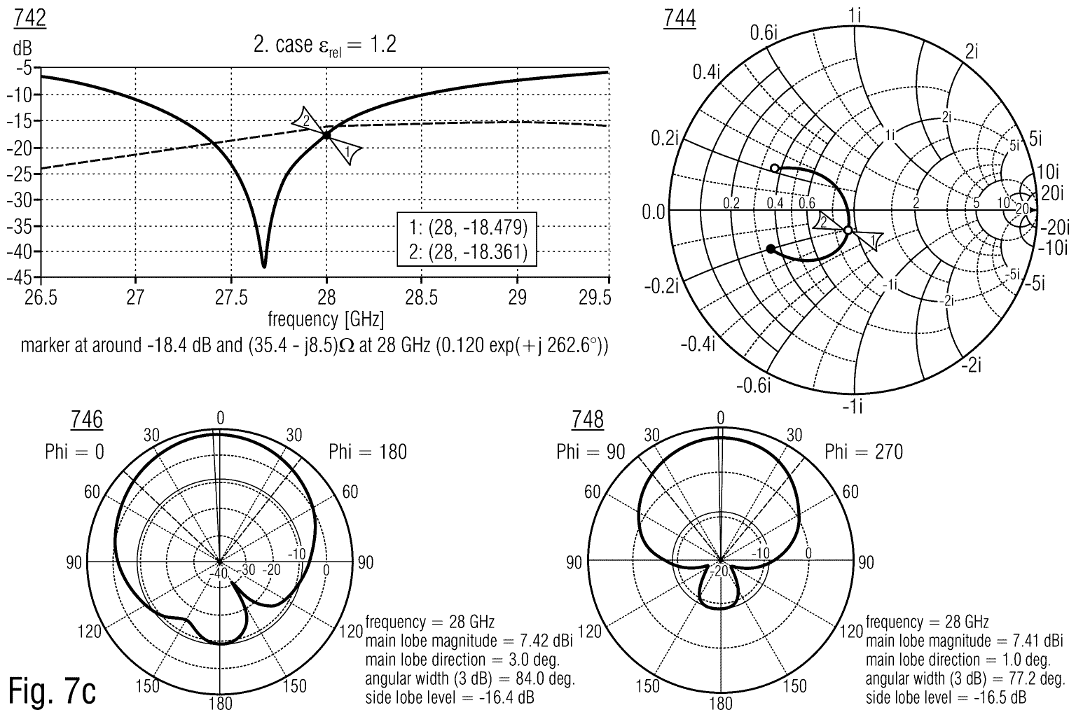

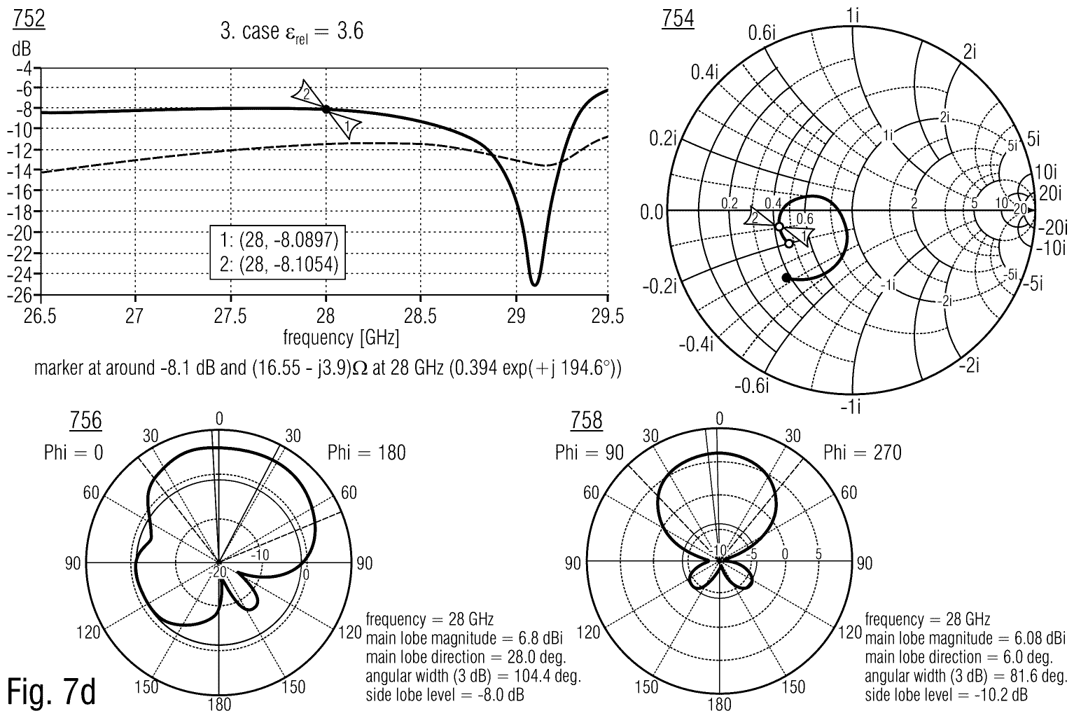

### Simulation of a Conventional Pusher According to FIG. 7

FIG. 7a shows a 3D simulation of an arrangement comprising a patch antenna 710 of a DUT, similar to the patch antenna 600 of FIG. 6, and a conventional solid dielectric pusher 720 configured to mechanically push a main surface of the DUT or the DUT-antenna into a DUT-socket, also shown in the design concept of FIG. 5b.

FIGS. 7b-d show results of simulated input reflection coefficient measurements conducted on the arrangement of FIG. 7a using different pushers, e.g. the pushers have different relative permittivity. In simulations a center frequency of operation of 28 GHz is used. The two feed lines are terminated in ports at a characteristic line impedance of about 35 Ohms.

FIG. 7b shows the results of a simulated input reflection coefficient measurement conducted on the first case of FIG. 7a, in which the pusher is made of a material with a relative permittivity of 1.0, such as air or vacuum. This equals to the fact that no pusher is present. Note, that the results presented in FIG. 6b, e.g. for an antenna of a device under test in air, is slightly different, because for an accurate comparison, in FIG. 7b the size of the computation domain is kept equal with or within all the simulations including the pusher. That is, in order to be able to compare the measurements of FIG. 7b-d, the domain of computation includes the pusher, while in the results presented in FIG. 6b it is not the case.

FIG. 7b shows input reflection coefficient measurement results of a simulation in which the pusher 720 is made of a material with a relative permittivity of 1, which is equal to not having a pusher. The simulation is taking account of the dimensions of the pusher, therefore the simulated measurement results are slightly different from the simulated measurement results presented in diagram 630 and Smith Chart 660 of FIG. 6.

The simulated measurement results of the input reflection coefficient is shown in the diagram 732 and in the Smith chart 734. Markers are at around −24.2 dB and (42.3+j1.2)Ω at 28 GHZ (0.0615 exp(+j13.7°)).

The radiation pattern in two exemplary, perpendicular cut-planes for one selected polarization of the dual-polarized antenna are shown in the diagrams 736, 738.

Radiation pattern results for the first cut plane is:
Frequency: 28 GHZ,
main lobe magnitude: 7.12 dBi,
main lobe direction: 3.0 deg.,
angular width (3 dB): 86.1 deg., and
side lobe level: −17.8 dB.

Radiation pattern results for the second cut plane is:
Frequency: 28 GHZ,
main lobe magnitude: 7.11 dBi,
main lobe direction: 1.0 deg.,
angular width (3 dB): 78.4 deg.,
side lobe level: −17.7 dB.

FIG. 7c shows the results of a simulated input reflection coefficient measurement conducted on the second case of FIG. 7a, in which the pusher 720 is made of a material with a relative permittivity of 1.2, for example a dielectric foam material. Similar to the first case, the results of the simulated reflection coefficient measurements are presented on the diagram 742 and on the Smith chart 744. Markers are at around −18.4 dB and (35.4−j8.5) (at 28 GHZ (0.120 exp(+j262.6°)).

Radiation pattern in two exemplary, perpendicular cut-planes for one selected polarization of the dual-polarized antenna are shown in the charts 746, 748.

Radiation pattern results for the first cut plane is:
Frequency: 28 GHZ,
main lobe magnitude: 7.42 dBi,
main lobe direction: 3.0 deg.,
angular width (3 dB): 84 deg., and
side lobe level: −16.4 dB.

Radiation pattern results for the second cut plane is:
Frequency: 28 GHZ,
main lobe magnitude: 7.41 dBi,
main lobe direction: 1.0 deg.,
angular width (3 dB): 77.2 deg.,
side lobe level: −16.5 dB.

FIG. 7d shows the results of a simulated input reflection coefficient measurement conducted on the third case of FIG. 7a, in which the pusher 720 is made of a material with a relative permittivity of 3.6, which might be a Polyetheretherketon (PEEK) material. The results of the simulated reflection coefficient measurements are presented on the diagram 752 and on the Smith chart 754. Markers are at around −8.1 dB and (16.55−j3.9)Ω at 28 GHz (0.394 exp(+j194.6°)).

Radiation pattern in two exemplary, perpendicular cut-planes for one selected polarization of the dual-polarized antenna are shown in the charts 756, 758.

Radiation pattern results for the first cut plane is:
Frequency: 28 GHZ,
main lobe magnitude: 6.8 dBi,
main lobe direction: 28.0 deg.,
angular width (3 dB): 104.4 deg., and
side lobe level: −8 dB.

Radiation pattern results for the second cut plane is:
Frequency: 28 GHZ,
main lobe magnitude: 6.08 dBi,
main lobe direction: 6.0 deg.,
angular width (3 dB): 81.6 deg.,
side lobe level: −10.2 dB.

In order to summarize the design concept used by conventional pushers 720, the simulated measurement results of FIG. 7b are compared to the simulated measurement results of FIG. 7c and FIG. 7d.

Comparing the first and second case, or the simulated measurement results of FIG. 7b and FIG. 7c, the feed reflection coefficient changed in the complex plane by 0.153, gain increased from 7.1 dBi to 7.4 dBi, and the beam width reduced from 86° to 84° (E-plane) respectively from 78° to 77° (H-plane). Such variation, and thus, such influence of the pusher is clearly acceptable. A material with a relative permittivity of 1.2, however, is mechanically not stiff enough.

Comparing the first and the third case, that is the simulated measurement results of FIG. 7b to the simulated measurement results of FIG. 7d, the feed reflection coefficient moved in the complex plane by 0.455, gain increase from 7.1 dBi to 6.8 dBi and beam width changed from 86° to 104° (E-plane) and respectively from 78° to 82° (H-plane). Such variation and thus, such influence of the pusher is too high, e.g. unacceptable.

The simulated measurement results, as shown in FIGS. 7b-d, of a conventional pusher, shown in FIG. 7a, is a demonstration that further design concepts or their combination are required.

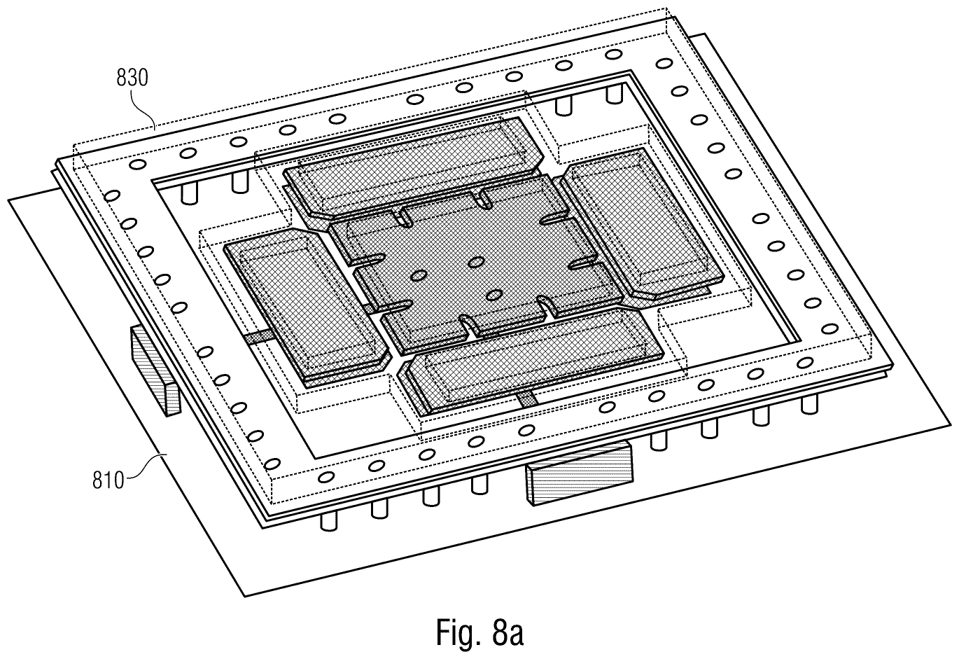

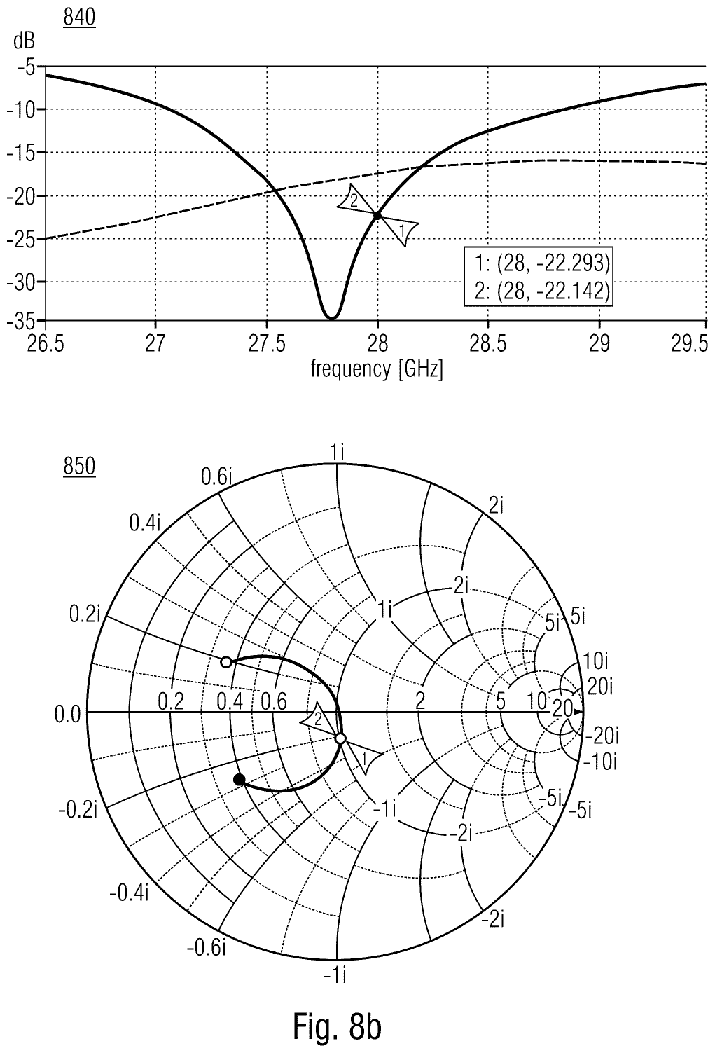

### Simulation of the Spacer According to FIG. 8

FIG. 8 shows a 3D simulation of a patch antenna 810, similar to the patch antenna 600 of FIG. 6, and a spacer 830, configured to push the DUT into a DUT-socket. The simulated spacer 830 is a low-permittivity spacer with a relative permittivity of 1.3, and an overall thickness of 300 micrometers. The spacer is considered to be touching the antenna surface. Further, the spacer provides (air-filter) trenches or cutouts of a depth of, for example, 150 micrometers along radiating edges or slots, with a trench width of, for example, 300 micrometers.

Results of the simulated reflection coefficient measurements are shown in the diagram 840 and in the Smith chart 850. Markers are at around −22.2 dB and (38.47−j5.8)Ω at 28 GHz (0.0077 exp(+j283.5°)).

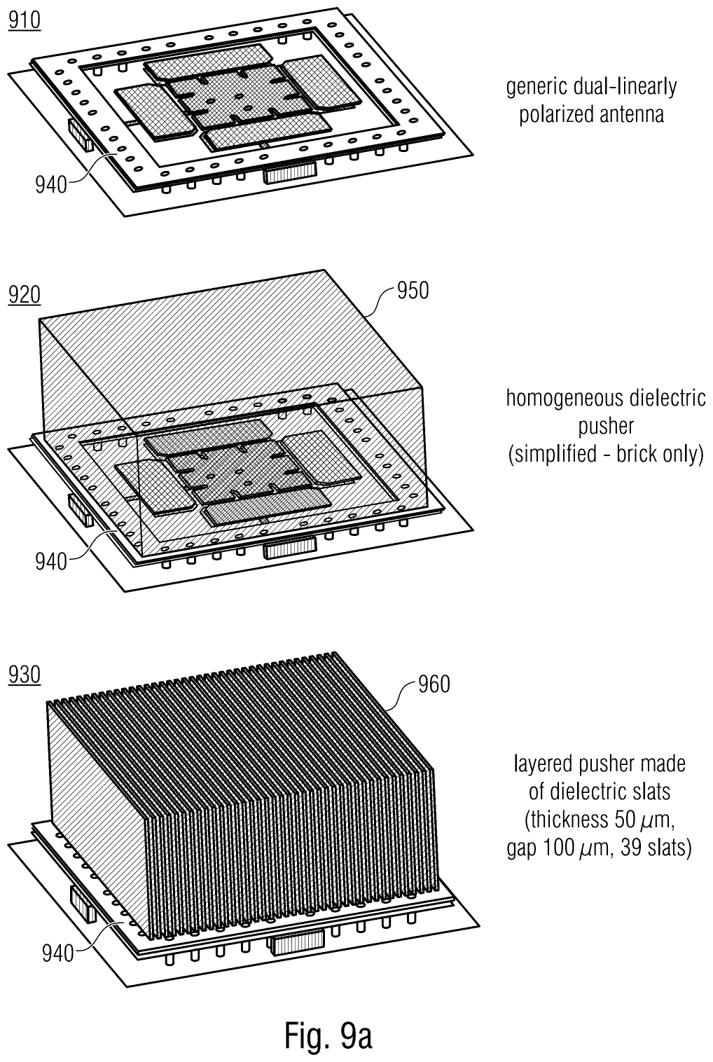

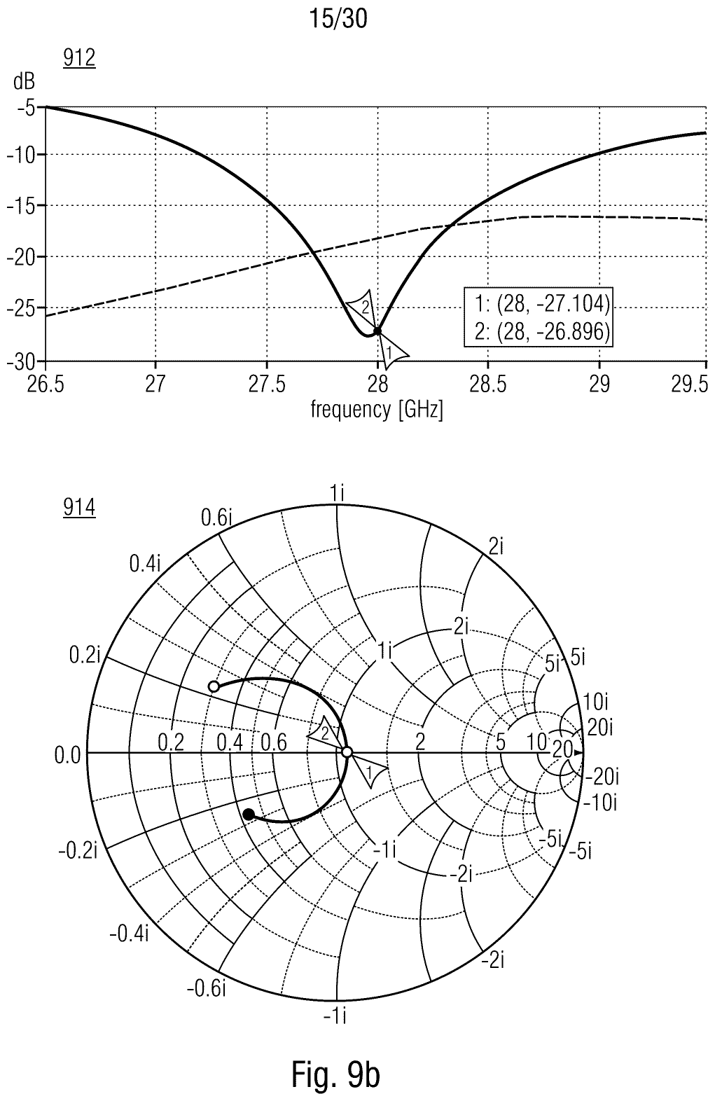

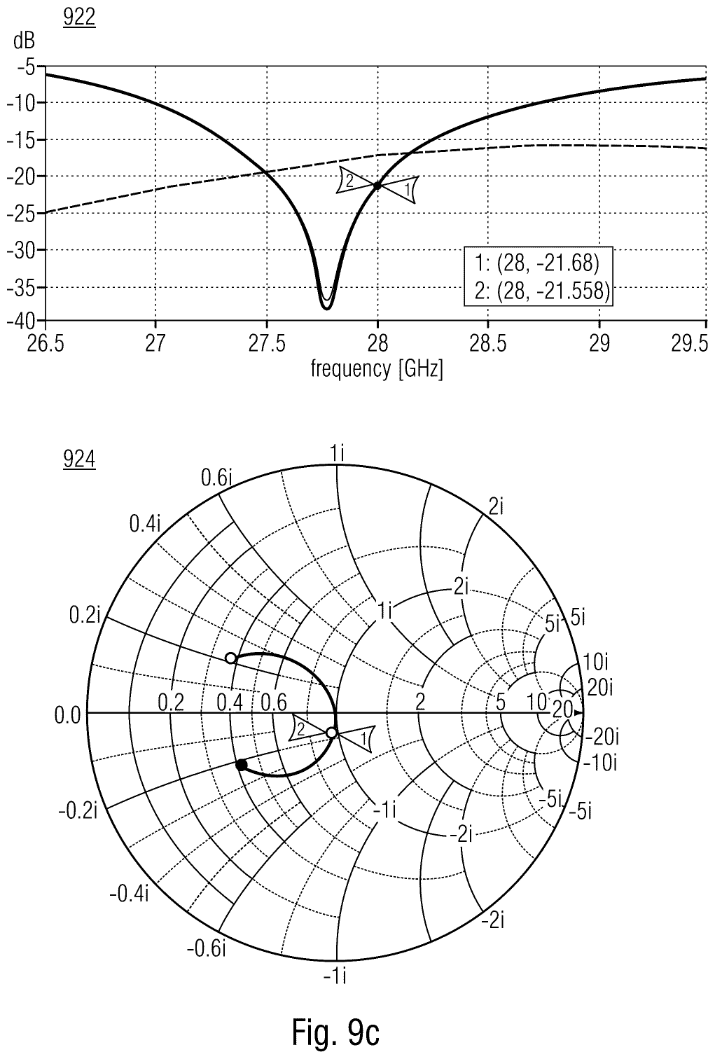

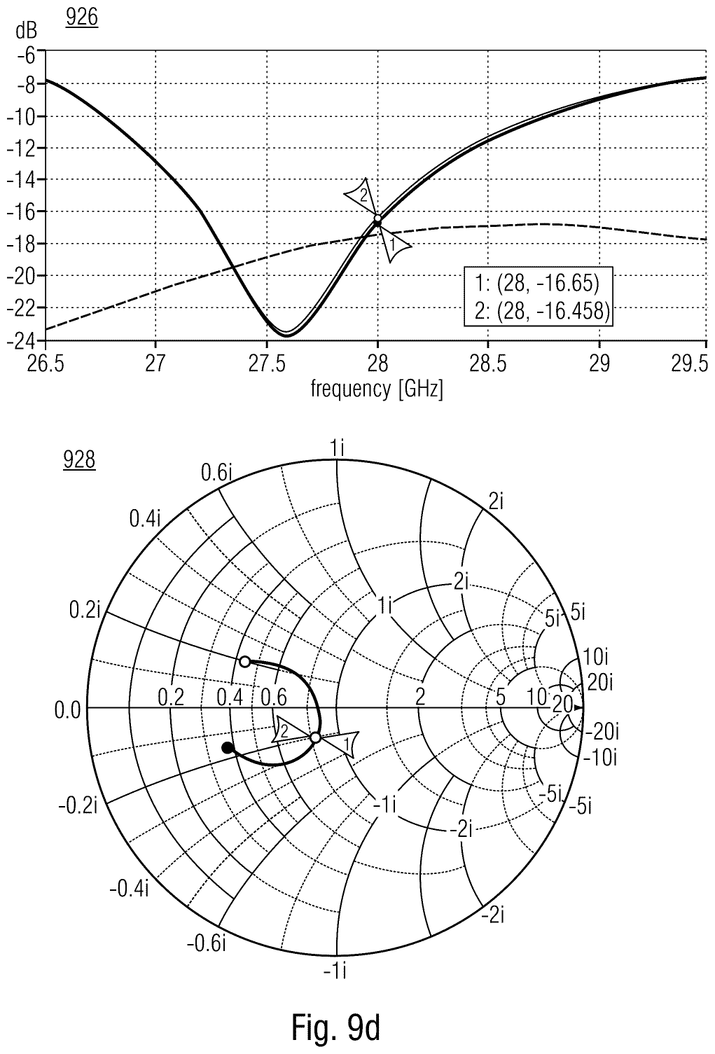

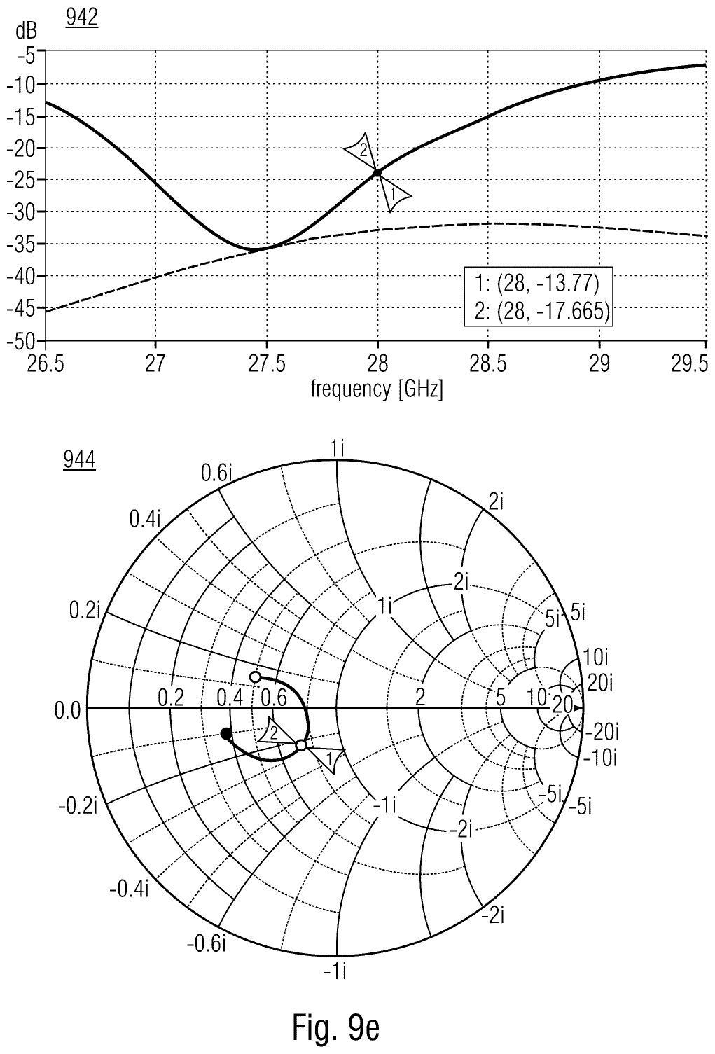

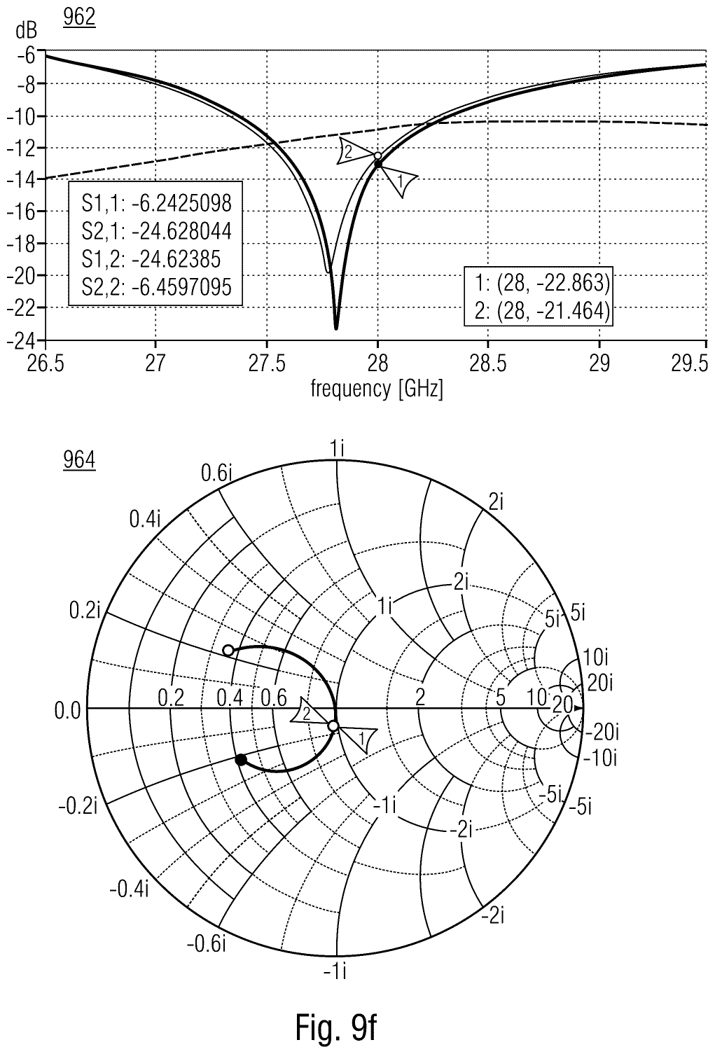

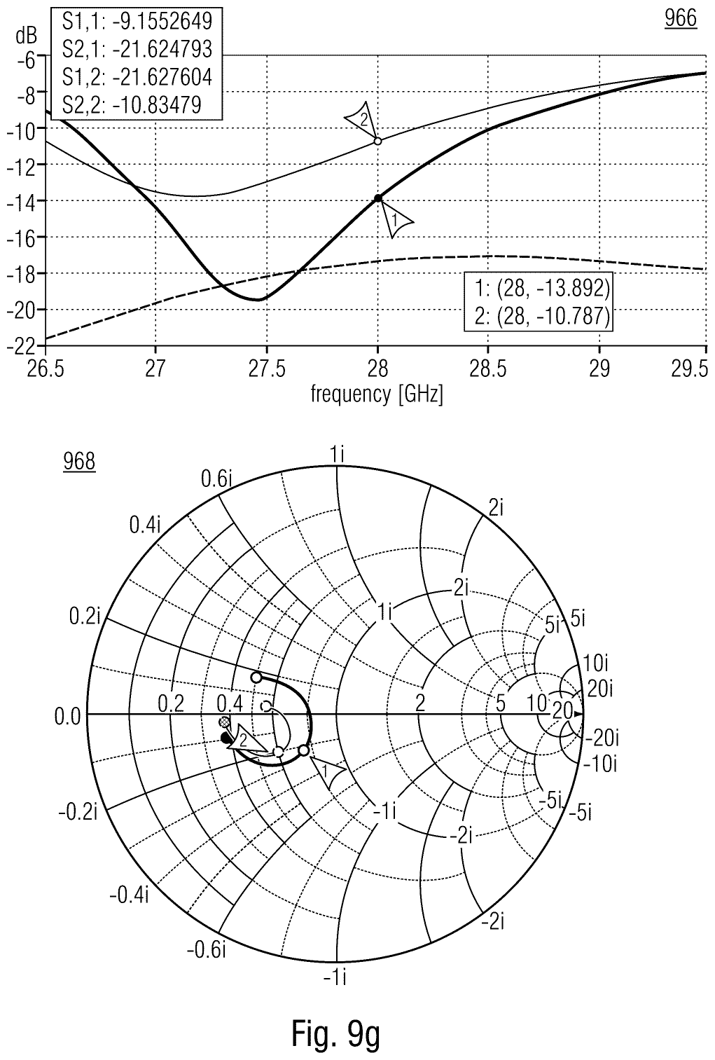

### Structure Design Simulation According to FIG. 9

FIG. 9a shows 3D simulations of three different test arrangements. The first 3D simulation of a test arrangement 910 is an initial example antenna 940 similar to the example antenna 600 of FIG. 6, which is a possible example of the patch antenna 500 of FIG. 5. The initial example antenna 940 is a dual-linearly polarized antenna or patch antenna. The example antenna 940 is used for quantifying performance in a simulation using electromagnetic field simulation software in the following second and third 3D simulated test arrangements.

The second 3D simulated test arrangement 920 comprise the initial example antenna 940 with a homogeneous dielectric pusher 950. The pusher 950 can be viewed as one block, or as a simplified brick only.

The third 3D simulated test arrangement 930 comprise the initial example antenna 940 with a pusher 960 with a structure of alternating layers or with a layered pusher 960, which is made of dielectric slats. In this example, the pusher has 39 slats, each having a thickness of 50 μm, with a gap of 100 μm between the neighboring slats.

FIG. 9b shows the results of a simulated input reflection coefficient measurement conducted on the first 3D simulated test arrangement 910 of FIG. 9a, in which no pusher is present. This is equivalent to the second test arrangement 920 of FIG. 9a with a pusher 950, which is a simplified brick and is made of a material with a relative permittivity of 1.0. The results of the simulated reflection coefficient measurements are presented on the diagram 912 and on the Smith chart 914. Markers are at around −24.2 dB and (40.9−j1.05)Ω at 28 GHZ (0.045 exp(+j343°)).

FIG. 9c shows the results of a simulated input reflection coefficient measurement conducted on the second 3D simulated test arrangement 920 of FIG. 9a, in which the pusher 950 is a simplified brick and is made of a material with a relative permittivity of 1.1. The results of the simulated reflection coefficient measurements are presented on the diagram 922 and on the Smith chart 924. Markers are at around −21.6 dB and (36.0−j5.92)Ω at 28 GHZ (0.083 exp(+j260°)).

FIG. 9d shows the results of a simulated input reflection coefficient measurement conducted on the second 3D simulated test arrangement 920 of FIG. 9a, in which the pusher 950 is a simplified brick and is made of a material with a relative permittivity of 1.2. The results of the simulated reflection coefficient measurements are presented on the diagram 926 and on the Smith chart 928. Markers are at around −16.55 dB and (31.22−j8.11)Ω at 28 GHZ (0.149 exp(+j239°)).

Similar to FIG. 9d, FIG. 9e shows the results of a simulated input reflection coefficient measurement conducted on the second 3D simulated test arrangement 920 of FIG. 9a, in which the pusher 950 is a simplified brick and is made of a material with a relative permittivity of 1.3. The results of the simulated reflection coefficient measurements are presented on the diagram 942 and on the Smith chart 944. Markers are at around −13.72 dB and (27.24−j8.67)Ω at 28 GHZ (0.206 exp(+j228°)).

FIG. 9f and FIG. 9g show the results of a simulated input reflection coefficient measurement conducted on the third 3D simulated test arrangement 930 of FIG. 9a, in which the pusher 950 is a layered pusher of 39 slats made of a material with a relative permittivity of 1.3 and 2.5 respectively. Each slat has a thickness of 50 μm, while the distance between two neighboring slats is 100 μm. The results of the simulated reflection coefficient measurements are presented on the diagrams 962 and 966 respectively and on the Smith charts 964 and 968 respectively.

Note, that the simulated measurement results of FIGS. 9b-e, e.g. measurements conducted on test arrangements without pusher or a simplified brick pusher, show no difference between the different polarizations of the example antenna, while measurement results of FIGS. 9f-g show, that a layered pusher affects the two perpendicular polarizations differently, e.g. the fields parallel to the slats (the first polarization or Port 1 feed) is less disturbed by the layered pusher as the fields which are perpendicular to the slats. That is, the curve and/or the marker for port 1 is different from the curve and/or the marker for port 2.

Marker of port 1 of FIG. 9f is at around −22.9 dB and (36.84−j5.32)Ω at 28 GHZ (0.072 exp(+j266°)). Marker of port 2 of FIG. 9f is at around −21.5 dB and (36.14−j6.08)Ω at 28 GHZ (0.085 exp(+j261°)).

Marker of port 1 of FIG. 9g is at around −13.9 dB and (27.66−j8.88)Ω at 28 GHz (0.202 exp(+j320°)). Marker of port 2 of FIG. 9g is at around −10.8 dB and (22.18−j8.16)Ω at 28 GHz (0.289 exp(+j216°)).

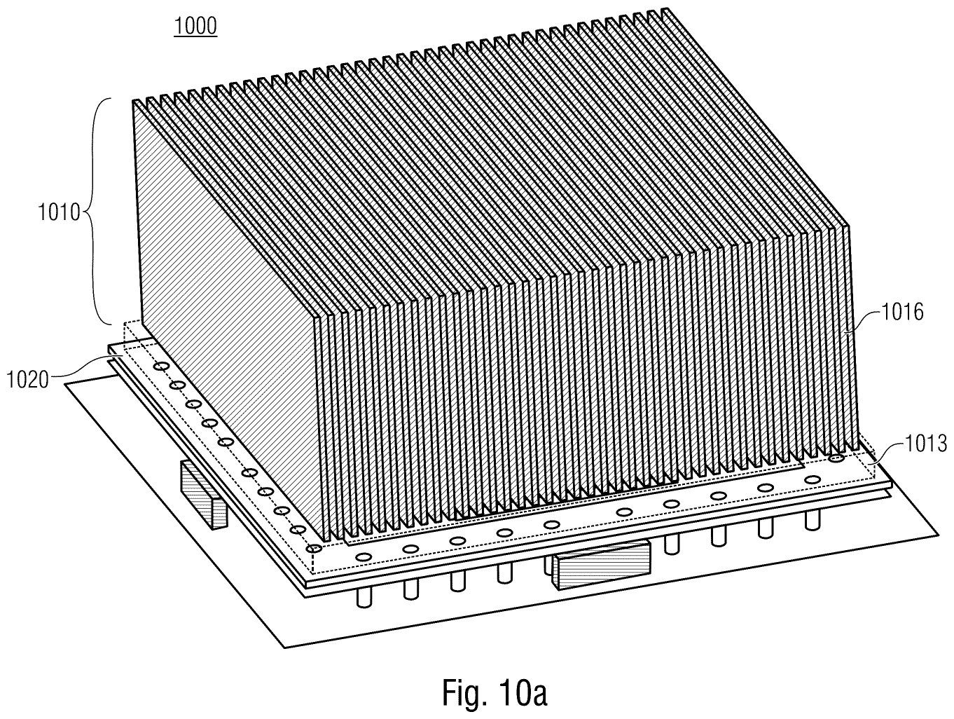

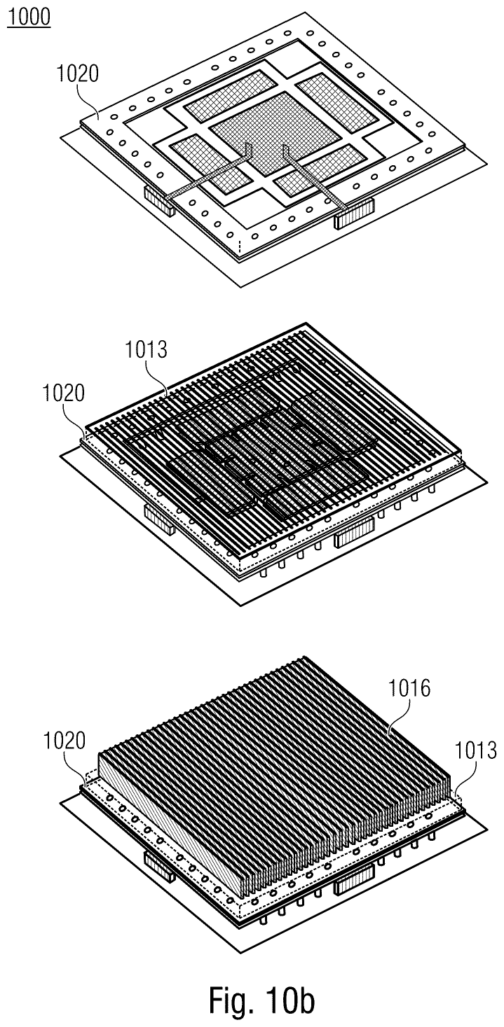

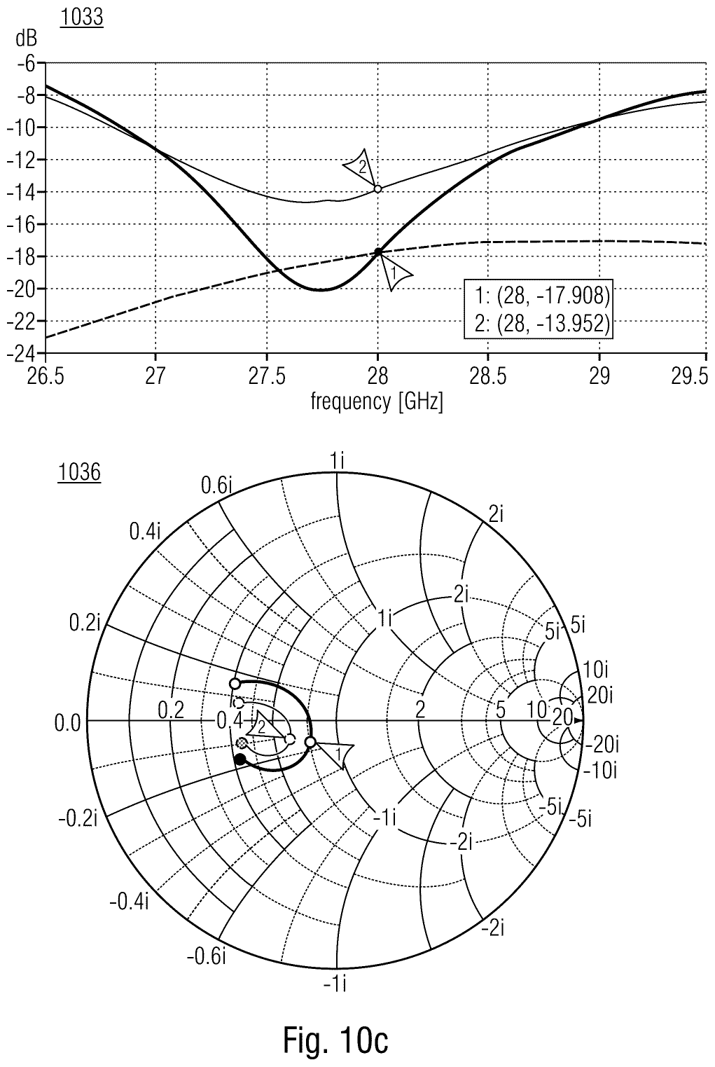

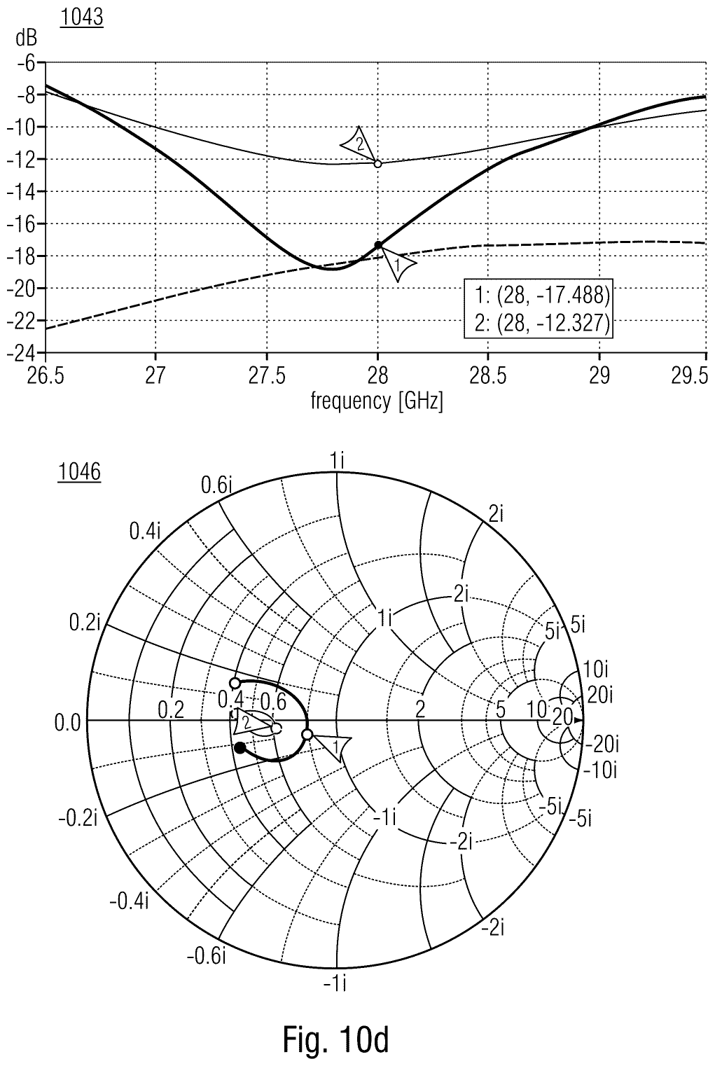

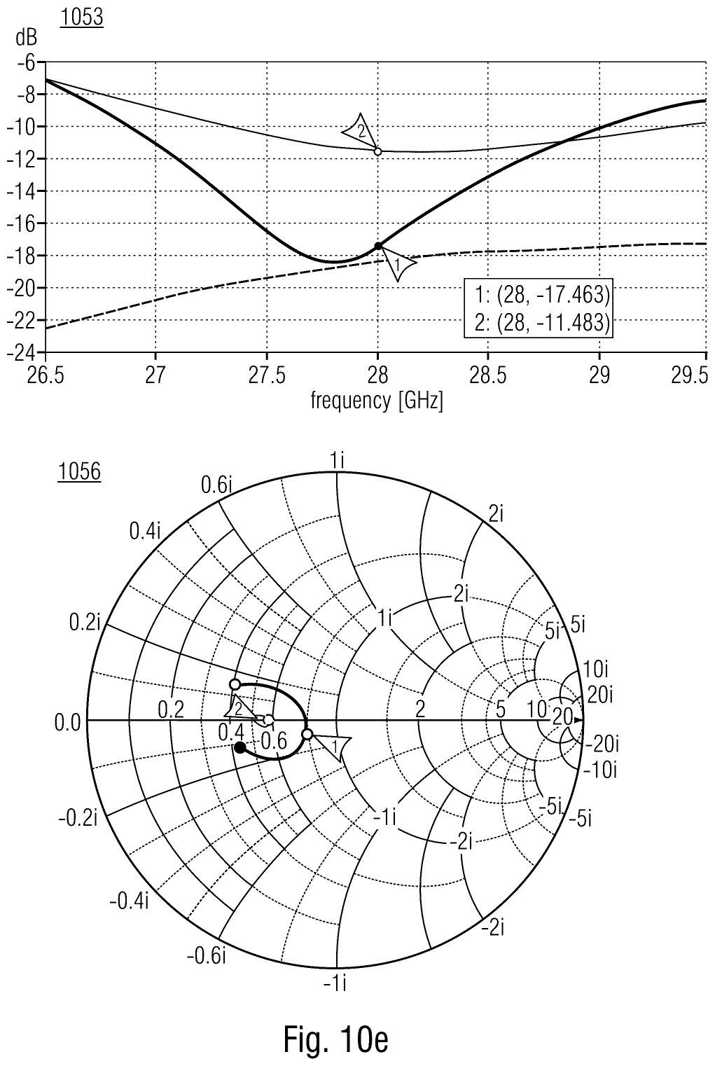

### Structure Design Simulation According to FIG. 10

FIG. 10a shows a 3D simulated test arrangement 1000 comprising a pusher 1010 and a DUT 1020 with an antenna. The pusher is a layered pusher, which comprises a low-permittivity structured spacer layer 1013, which is made of a material with a relative permittivity of 1.3, combined with a structure of alternating layers 1016. In this example, the structure 1016 has 39 dielectric slats, where a slat has a thickness of 50 μm, with a distance or gap between two neighboring slats of 100 μm. In this simulation, the material of the slats has a variable permittivity, e.g. measurements conducted on different pushers made of different slat-materials can be simulated.

In order to make it more visible, the test arrangement 1000 is shown or built up layer by layer in FIG. 10b. The first image shows the DUT 1020 with antenna, which is a of a dual-polarized patch antenna similar to the antenna 600 of FIG. 6a. The second image shows the DUT 1020 with the low-permittivity spacer layer 1013 of the pusher 1010. The third image shows the 3D simulated test arrangement 1000 comprising the DUT 1020 and the pusher 1010 with the structured spacer layer 1013 and the alternating layers 1016.

FIG. 10c shows the results of a simulated input reflection coefficient measurement conducted on the 3D simulated test arrangement 1000 of FIG. 10a, in which the pusher 1010 is a layered pusher of 39 slats with a structured spacer layer 1013. The structured spacer layer 1013 and the slats are made of a material with a relative permittivity of 1.3 and 2.5 respectively. The results of the simulated reflection coefficient measurements are presented on the diagram 1033 and on the Smith chart 1036.

Marker of port 1 of FIG. 10c is at around −17.9 dB and (30.4−j4.9)Ω at 28 GHZ (0.127 exp(+j218.6°)). Marker of port 2 of FIG. 10c is at around −13.9 dB and (25.5−j4.1)Ω at 28 GHz (0.201 exp(+j202.5°)).

FIG. 10d shows the results of a simulated input reflection coefficient measurement conducted on the 3D simulated test arrangement 1000 of FIG. 10a, in which the pusher 1010 is a layered pusher of 39 slats with a structured spacer layer 1013. The structured spacer layer 1013 and the slats are made of a material with a relative permittivity of 1.3 and 3.1 respectively. The results of the simulated reflection coefficient measurements are presented on the diagram 1043 and on the Smith chart 1046.

Marker of port 1 of FIG. 10d is at around −17.5 dB and (29.6−j4.2)Ω at 28 GHz (0.133 exp(+j211.2°)). Marker of port 2 of FIG. 10d is at around −12.3 dB and (23.1−j2.2)Ω at 28 GHz (0.242 exp(+j190.9°)).

FIG. 10e shows the results of a simulated input reflection coefficient measurement conducted on the 3D simulated test arrangement 1000 of FIG. 10a, in which the pusher 1010 is a layered pusher of 39 slats with a structured spacer layer 1013. The structured spacer layer 1013 and the slats are made of a material with a relative permittivity of 1.3 and 3.6 respectively. The results of the simulated reflection coefficient measurements are presented on the diagram 1053 and on the Smith chart 1056.

Marker of port 1 of FIG. 10e is at around −17.5 dB and (29.6−j3.5)Ω at 28 GHz (0.134 exp(+j206°)). Marker of port 2 of FIG. 10e is at around −11.5 dB and (21.7−j0.7)Ω at 28 GHZ (0.267 exp(+j183°)).

The simulated measurement results show, that a layered pusher 1010 affects the two perpendicular polarizations differently, e.g. the fields parallel to the slats (the first polarization or Port 1 feed) is less disturbed by the layered pusher as the fields which are perpendicular to the slats.

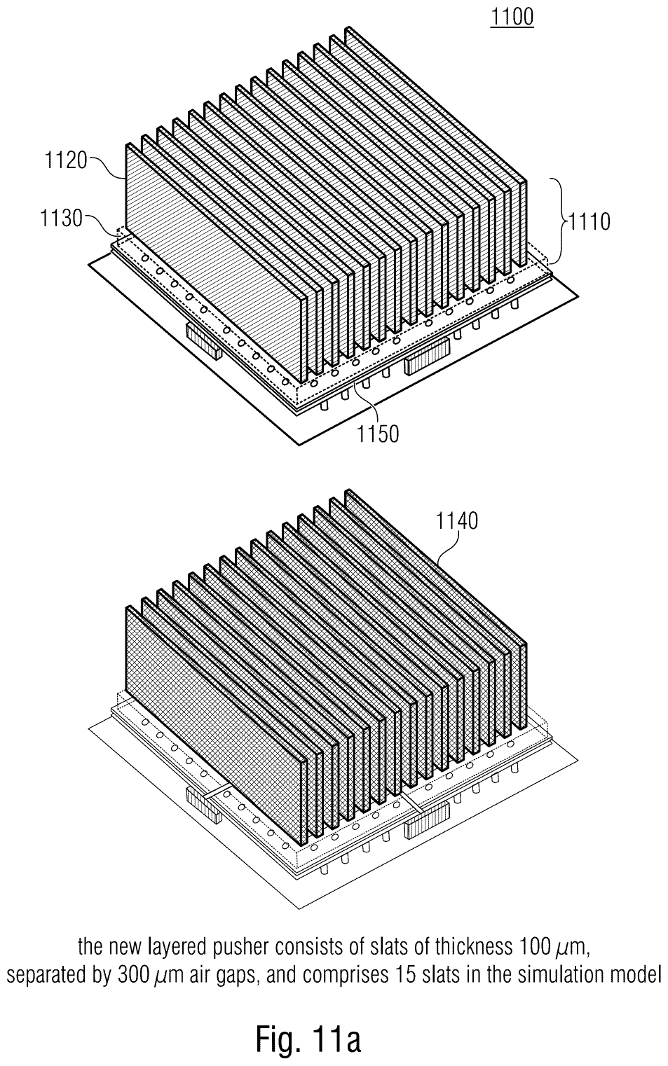

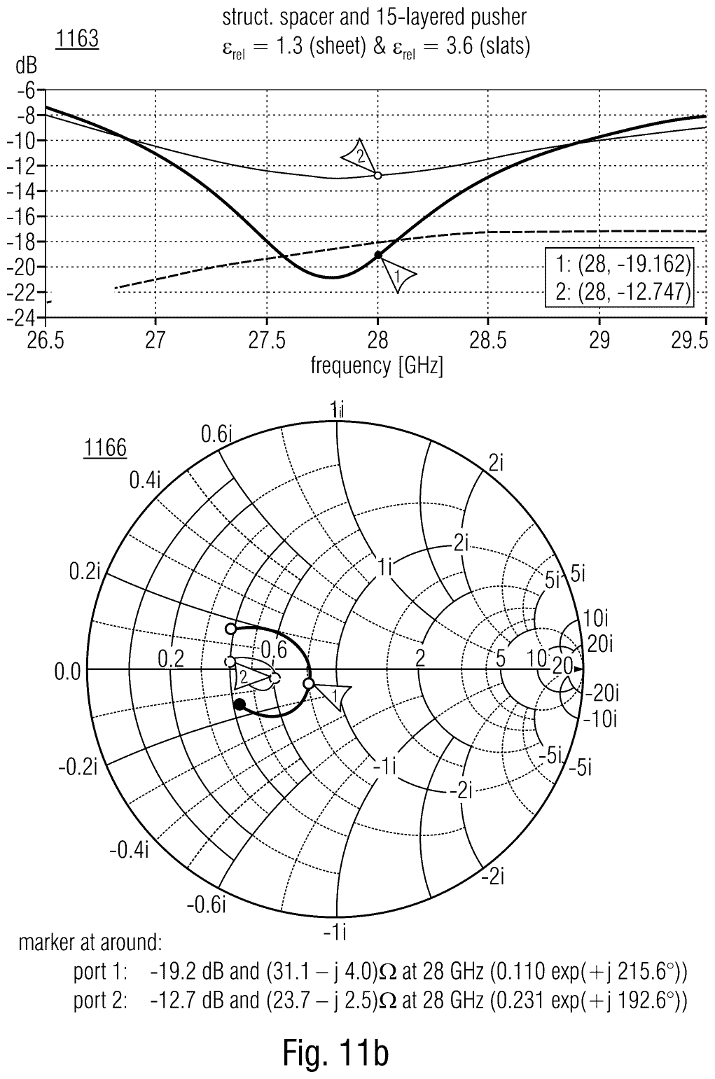

### Structure Design Simulation According to FIG. 11

FIG. 11a shows two images of the same 3D simulated test arrangement 1100 comprising a pusher 1110 and a DUT 1150 with an antenna. The first image focusses on the test arrangement 1100, while the second image focuses on the slats 1140 of the pusher 1110. The pusher 1110 is a layered pusher 1110, which comprises a low-permittivity structured spacer layer 1130, which is made of a material with a relative permittivity of 1.3, combined with a structure of alternating layers 1120 or slats 1140 separated by air gaps. In this simulation model or example, the structure 1120 has 15 dielectric slats 1140, where a slat 1140 has a thickness of 100 μm, the neighboring slats 1140 are separated by an air gap of 300 μm. Slats 1140 are made of a material with a relative permittivity of 3.6.

Even though the material of the low-permittivity spacer 1130 or spacer layer 1130 is rather soft, the spacer layer 1130 helps to distribute pressure. Therefore, the density of layers or slats 1140 in the layered pusher 1110 could be (somewhat) reduced, which reduces the disturbance of the feed reflection coefficient. This is also recognizable when comparing the simulated measurement results of FIG. 10 and FIG. 11.

FIG. 11b shows the results of a simulated input reflection coefficient measurement conducted on the 3D simulated test arrangement 1100 of FIG. 11a, in which the pusher 1110 is a layered pusher of 15 slats 1140 with a structured spacer layer 1130. The structured spacer layer 1130 and the slats 1140 are made of a material with a relative permittivity of 1.3 and 3.6 respectively. The results of the simulated reflection coefficient measurements are presented on the diagram 1163 and on the Smith chart 1166.

The layered pusher 1110 affects the two perpendicular polarizations differently, e.g. the fields parallel to the slats 1140 (the first polarization or Port 1 feed) is less disturbed by the layered pusher 1110 as the fields which are perpendicular to the slats 1140.

Marker of port 1 of FIG. 11b is at around −19.2 dB and (31.1−j4.0)Ω at 28 GHz (0.110 exp(+j215.6°)). Marker of port 2 of FIG. 11b is at around −12.7 dB and (23.7−j2.5)Ω at 28 GHZ (0.231 exp(+j192.6°)).

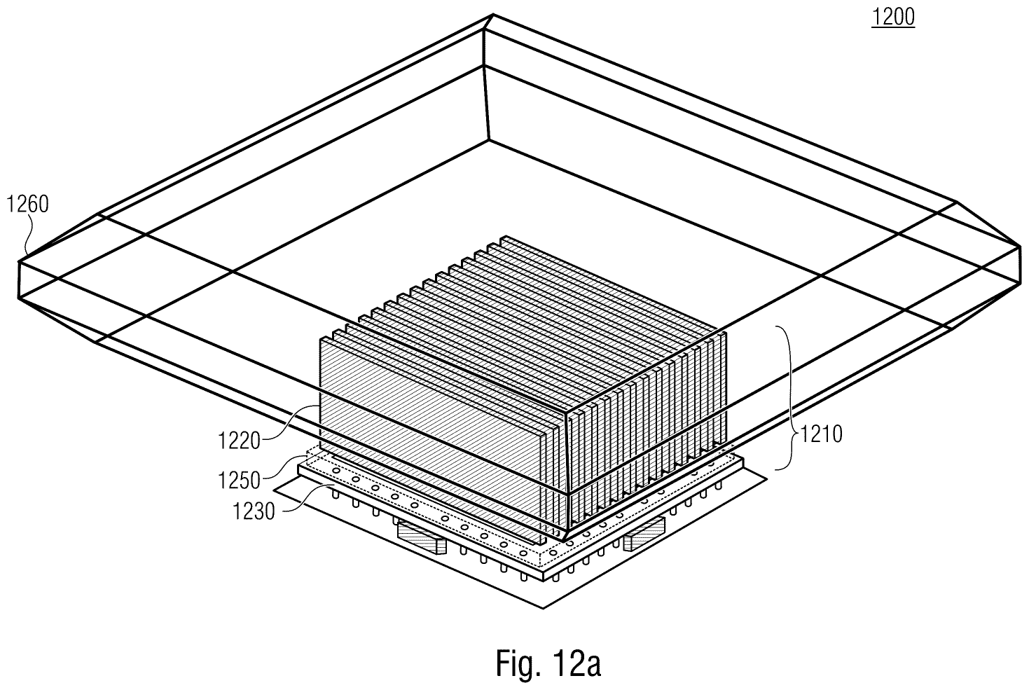

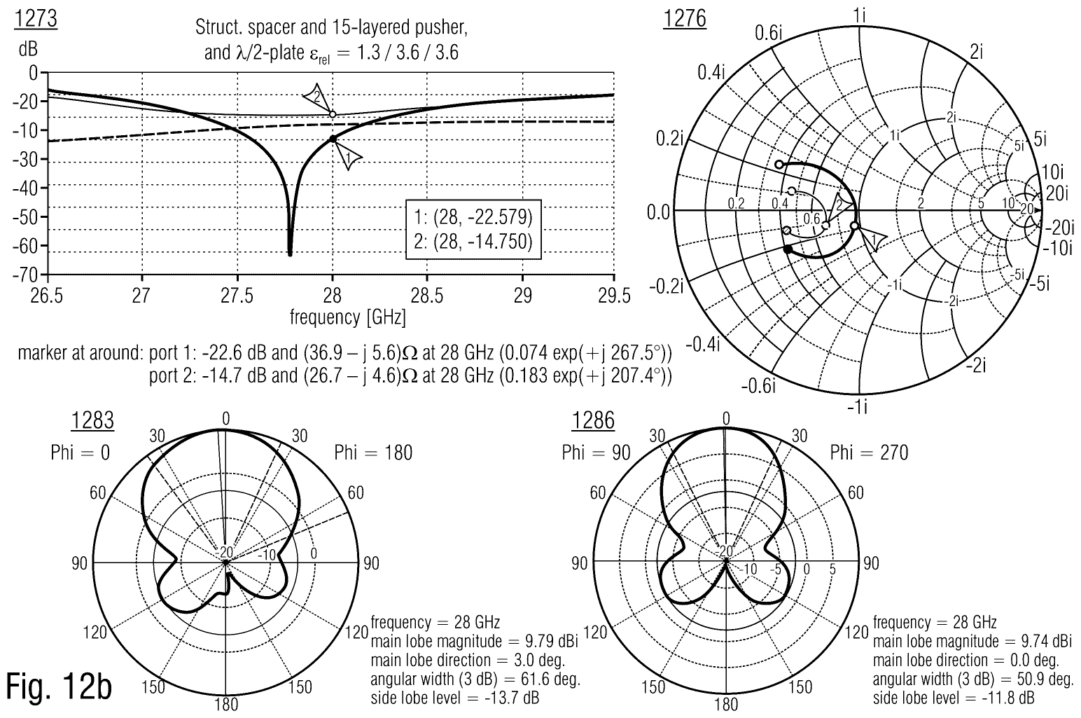

### Structure Design Simulation According to FIG. 12

FIG. 12a shows a simulated test arrangement 1200, similar to the simulated test arrangement 1100 of FIG. 11, with the pusher 1210 having an additional dielectric slab 1260. That is, the simulated test arrangement 1200 comprises a pusher 1210 and a DUT 1250 with an antenna. The pusher 1210 is a layered pusher 1210, which comprises a low-permittivity structured spacer layer 1230, which is made of a material with a relative permittivity of 1.3, combined with a structure of alternating layers 1220 and with a dielectric slab 1260 attached to the structure of alternating layers 1220. In this simulation model or example, the structure 1220 has 15 dielectric slats, where a slat has a thickness of 100 μm, the neighboring slats are separated by an air gap of 300 μm. Slats 1140 are made of a material with a relative permittivity of 3.6. The dielectric slab 1260 or dielectric plate 1260 of about half-wavelength thickness, e.g. 2.82 mm for a relative permittivity of 3.6 is added to provide a mechanically realistic and stable pusher structure.

FIG. 12b shows results of a simulated input reflection coefficient measurements conducted on the 3D simulated test arrangement of FIG. 12a, in which the pusher 1210 is a layered pusher of 15 slats with a structured spacer layer 1230. The structured spacer layer 1230, the slats and the dielectric slab 1260 are made of materials with relative permittivity of 1.3, 3.6 and 3.6 respectively. The results of the simulated reflection coefficient measurements are presented on the diagram 1273 and on the Smith chart 1276.

Marker of port 1 of FIG. 12b is at around −22.6 dB and (36.9−j5.5)Ω at 28 GHz (0.074 exp(+j267.5°)). Marker of port 2 of FIG. 12b is at around −14.7 dB and (26.7−j4.6)Ω at 28 GHZ (0.183 exp(+j207.4°)).

The radiation pattern in two exemplary, perpendicular cut-planes for one selected polarization of the dual-polarized antenna are shown in the diagrams 1283 and 1286.

Radiation pattern results for the first cut plane is:
Frequency: 28 GHZ,
main lobe magnitude: 9.79 dBi,
main lobe direction: 3.0 deg.,
angular width (3 dB): 61.6 deg., and
side lobe level: −13.7 dB.

Radiation pattern results for the second cut plane is:
Frequency: 28 GHZ,
main lobe magnitude: 9.74 dBi,
main lobe direction: 0.0 deg.,
angular width (3 dB): 50.9 deg.,
side lobe level: −11.8 dB.

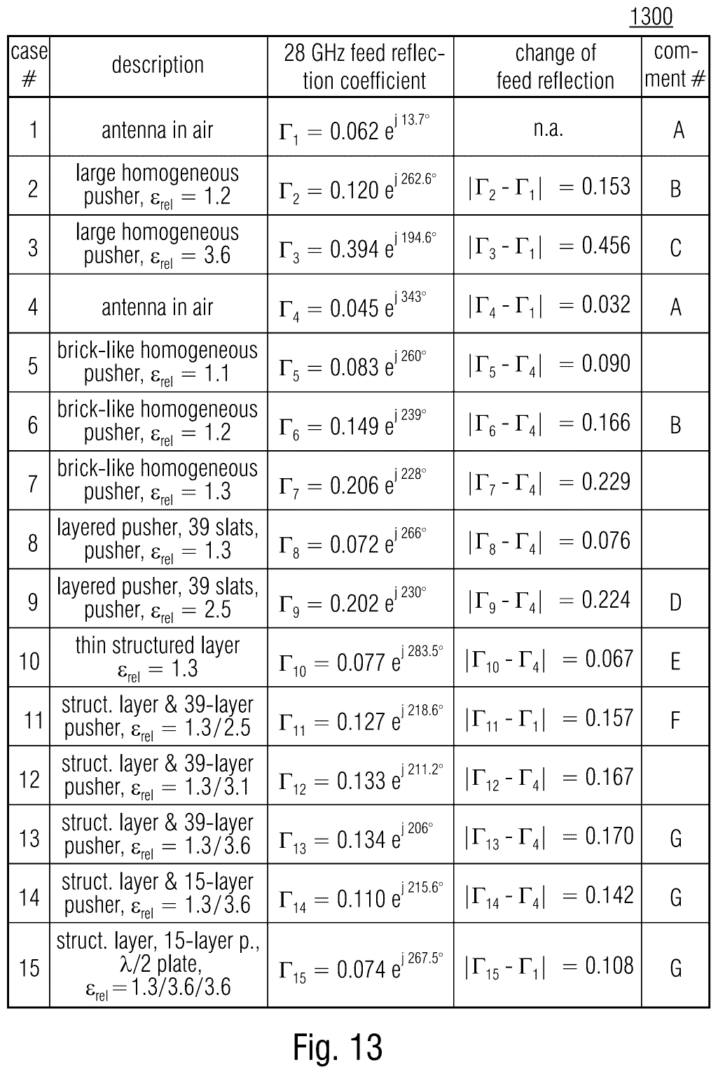

FIG. 13 shows a comparison table 1300 with respect to the change of feed reflection coefficient. That is, for different cases, described in the column “description”, the 28 GHz feed reflection coefficient and the change of feed reflection is indicated in the table. Comments related to cases indicated by letters in the last column of the table are to be found below:
A A small difference between simulations of a structure “antenna only”, i.e., without any pusher, can be attributed to different size of “air volume” in the computational domain and to different mesh.
B According to measurements, using pusher made of homogeneous foam dielectric of permittivity εᵣₑₗ=1.2, such change of feed reflection is acceptable, although it is not known, to what extent a (somewhat) larger change would be acceptable, too.
C A material with permittivity of εᵣₑₗ=3.6, such as PEEK, when used for a homogeneous pusher, leads to completely unacceptable disturbance of the antenna.
D This is an illustrative example showing the significant reduction of antenna disturbance using the layered-sheet pusher—if the respective orientations of electric field and pusher layers are appropriate. The orthogonal polarization (feeding the other port of the patch antenna) leads to a change of reflection coefficient of |Γ_{9,port2}−Γ₄]=0.318—much larger than the 0.224 reported for the “correct” polarization. This difference increases for larger permittivity of the layers, e.g., case #13, with εᵣₑₗ=3.6, a change of 0.310 versus 0.170, depending on orientation of layers and fields.
E The thin structured spacer layer is supposedly made of foam (εᵣₑₗ=1.3), which is soft but stiff enough in small thickness (0.3 mm). This spacer layer is to be machined specifically depending on the layout of the antenna (array) aperture surface.
F Comparing case #9 with case #11, it is obvious that the introduction of a thin structured spacer layer reduces the change of feed reflection coefficient (very) significantly.
G Using the thin structured spacer layer (εᵣₑₗ=1.3) and the layered-sheet pusher (made of PEEK, εᵣₑₗ=3.6), the change of feed reflection coefficient is sufficiently small. It can be further reduced by design features, such as increasing the period of the layered sheets, reducing the dielectric volume fraction in the layered-sheet component, or adding a halfwave-plate. Note that the performance of such structures only holds for single-linearly polarized antennas and arrays.

Regarding the radiation pattern, a focusing effect, e.g. a higher directivity and narrower beam in a direction perpendicular to the antenna surface, is caused by the dielectric pusher. As long as this effect is small, it does not affect significantly negatively the testing application. With the exception of illustrative case no. 3, e.g. a full homogenous PEEK pusher, all other pushers cause small pattern changes only.

In conclusion, the proposed concept allows the realization of an “electromagnetically transparent” pusher primarily made of high-permittivity material for single-linear polarization antennas.

### Implementation Alternatives

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus. In some embodiments, one or more of the most important method steps may be executed by such an apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A pusher for use in an automated test equipment to mechanically push a device under test into a device under test socket, the pusher comprising:
a structure in which there are alternating layers of higher dielectric permittivity and layers of lower dielectric permittivity;
wherein the layers of higher dielectric permittivity and the layers of lower dielectric permittivity extend in a first direction, which is within +/−45° of a pushing direction.

2. The pusher according to claim 1,
wherein a ratio between a thickness of the layers of the higher dielectric permittivity and a thickness of the layers of lower dielectric permittivity is between 1:10 and 2:1.

3. The pusher according to claim 1,
wherein the alternating layers comprise between 9 vol. % and 66.6 vol. % higher dielectric permittivity regions and between 91 vol. % and 33.3 vol. % lower dielectric permittivity regions.

4. The pusher according to claim 1, further comprising:
a spacer;
wherein the alternating layers are parallel layers;
wherein the spacer is configured to be in between the alternating layers and the device under test;
wherein the spacer is perpendicular, within a tolerance of +/−15°, to the alternating layers, or
wherein the spacer is parallel, within a tolerance of +/−15°, to a surface of the device under test to be pushed by the pusher.

5. The pusher according to claim 4,
wherein the spacer is configured to touch the device under test; and
wherein the spacer is configured to avoid touching or approaching, within a distance of 1/10 of a wavelength of an electromagnetic wave transmitted or received by an antenna of the device under test, a conductive edge of the antenna of the device under test.

6. The pusher according to claim 4,
wherein the spacer comprises a relative permittivity less than or equal to 1.5.

7. The pusher according to claim 4,
wherein the spacer comprises a thickness of between 50 micrometers and 500 micrometers.

8. The pusher according to claim 7,
wherein the spacer comprises a thickness of between 100 micrometers and 200 micrometers.

9. The pusher according to claim 1, further comprising:
a dielectric slab;
wherein the dielectric slab is transversal or perpendicular, within a tolerance of +/−15°, to the pushing direction,
wherein the dielectric slab is configured to mechanically support the layers of higher dielectric permittivity.

10. The pusher according to claim 9,
wherein the alternating layers are parallel layers; and
wherein a length of the alternating layers in the pushing direction is between 0.5 times a free space wavelength of an electromagnetic wave transmitted or received by the antenna of the device under test and 2 times a free space wavelength of the electromagnetic wave transmitted or received by the antenna of the device under test.

11. The pusher according to claim 1,
wherein the layers of higher dielectric permittivity comprise a relative permittivity greater than 2.

12. The pusher according to claim 1,
wherein the layers of higher dielectric permittivity are made of polymer or of polycarbonate or of quartz or of Teflon or of PEEK material.

13. The pusher according to claim 1,
wherein the layers of lower dielectric permittivity comprise a relative permittivity less than or equal to 1.5.

14. The pusher according to claim 1,
wherein the layers of lower dielectric permittivity comprise air.

15. The pusher according to claim 1,
wherein the pushing direction is perpendicular, within a tolerance of +/−15°, to a far-field direction of an electrical field in a main lobe of an antenna of the device under test, or
wherein the pushing direction is perpendicular, within a tolerance of +/−15°, to a main surface of device under test, or
wherein the pushing direction is perpendicular, within a tolerance of +/−15°, to a main surface of device under test socket.

16. A test arrangement for testing a device under test, the test arrangement comprising:
a device under test;
a device under test socket; and
a pusher according to claim 1;
wherein the device under test comprises an an antenna; and
wherein the device under test is pushed into the device under test socket by the pusher in order to test the device under test.

17. The test arrangement according to claim 16,
wherein the pusher comprises a dielectric slab transversal or perpendicular, within a tolerance of +/−15°, to the pushing direction,
wherein the dielectric slab is configured to mechanically support the layers of higher dielectric permittivity, and
wherein the dielectric slab of the pusher comprises a thickness which equals, within a tolerance of 1/10 of a wavelength of an electromagnetic wave transmitted or received by the antenna of the device under test, to an integer multiple of a half wavelength of the electromagnetic wave, in a dielectric material of the dielectric slab, transmitted or received by the antenna of the device under test, and
wherein a distance between the dielectric slab of the pusher and a surface of the antenna of the device under test is at least one wavelength of the electromagnetic wave transmitted or received by the antenna of the device under test.

18. The test arrangement according to claim 16,
wherein the alternating layers are parallel layers; and
wherein a length of the alternating layers of the pusher in the pushing direction is between 0.5 times a free space wavelength of an electromagnetic wave transmitted or received by the antenna of the device under test and 2 times the free space wavelengths of the electromagnetic wave transmitted or received by the antenna of the device under test.

19. The test arrangement according to claim 16,
wherein the pusher comprises a surface configured to touch the device under test; and
wherein the surface configured to touch the device under test is formed so that the pusher avoids touching or approaching, within a distance of 1/10 of a wavelength of an electromagnetic wave transmitted or received by the antenna of the device under test, a conductive edge of the antenna of the device under test.

20. A method for mechanically pushing a device under test into a device under test socket of an automated test equipment, the method comprising:
mechanically pushing the device under test into the device under test socket with a pusher,
wherein the pusher comprises a structure in which there are alternating layers of higher dielectric permittivity and layers of lower dielectric permittivity, and
wherein the alternating layers are extending in a first direction, which is within +/−45° of a pushing direction.
